(19) United States
(12) Patent Application Publication
(10) Pub. No.: US 2010/0051085 A1
(43) Pub. Date: Mar. 4, 2010

(54) BACK CONTACT SOLAR CELL MODULES

(76) Inventors: Timothy W. Weidman, Sunnyvale, CA (US); Charles Gay, Westlake Village, CA (US); Hsiu-Wu (Jason) Guo, Alviso, CA (US); Rohit Mishra, Santa Clara, CA (US); Kapila P. Wijekoon, Palo Alto, CA (US); Hemant Mungekar, Campbell, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/549,291

(22) Filed: Aug. 27, 2009

Related U.S. Application Data
(60) Provisional application No. 61/092,379, filed on Aug. 27, 2008.
(60) Provisional application No. 61/105,029, filed on Oct. 13, 2008.
(60) Provisional application No. 61/139,423, filed on Dec. 19, 2008.
(60) Provisional application No. 61/158,675, filed on Mar. 9, 2009.
(60) Provisional application No. 61/184,720, filed on Jun. 5, 2009.

(51) Int. Cl. H01L 31/042; H01L 31/18

(52) U.S. Cl. 136/244; 438/98

(57) ABSTRACT

Embodiments of the invention contemplate the formation of a high efficiency solar cell using a novel processing sequence to form a solar cell device. Methods of forming the high efficiency solar cell may include the use of a prefabricated back plane that is bonded to the metalized solar cell device to form an interconnected solar cell module. Solar cells most likely to benefit from the invention including those having active regions comprising single or multicrystalline silicon with both positive and negative contacts on the rear side of the cell.

### CROSS-REFERENCE TO RELATED APPLICATIONS

This application claims benefit of U.S. Provisional Patent Application Ser. No. 61/092,379 [Attorney Docket #: APPM 13437L], filed Aug. 27, 2008, U.S. Provisional Patent Application Ser. No. 61/105,029 [Attorney Docket #: APPM 13437L02], filed Oct. 13, 2008, U.S. Provisional Patent Application Ser. No. 61/139,423 [Attorney Docket #: APPM 13437L03], filed Dec. 19, 2008, U.S. Provisional Patent Application Ser. No. 61/158,675 [Attorney Docket #: APPM 13858L], filed Mar. 9, 2009 and U.S. Provisional Patent Application Ser. No. 61/184,720 [Attorney Docket #: APPM 13858L02], filed Jun. 5, 2009, which are all herein incorporated by reference in their entirety.

### BACKGROUND OF THE INVENTION

1. Field of the Invention

Embodiments of the invention generally relate to the fabrication of photovoltaic cells.

2. Description of the Related Art

Solar cells are photovoltaic devices that convert sunlight directly into electrical power. Each solar cell generates a specific amount of electric power and are typically tiled into modules sized to deliver the desired amount of system power. The most common solar cell material is silicon, which is in the form of single or multicrystalline substrates, sometimes referred to as wafers. Because the amortized cost of forming silicon-based solar cells to generate electricity is higher than the cost of generating electricity using traditional methods, there has been an effort to reduce the cost to form solar cells.

Various approaches enable fabricating active regions of the solar cell and the current carrying metal lines, or conductors, of the solar cells. However, there are several issues with these prior manufacturing methods. For example, the formation processes are complicated multistep processes that add to costs required to complete the solar cells.

Therefore, there exists a need for improved methods and apparatus to form the active and current carrying regions formed on a surface of a substrate to form a solar cell.

### SUMMARY OF THE INVENTION

The present invention generally provides an interconnect structure used to electrically connect portions of a first solar cell device having a first solar cell substrate to a second solar cell device, comprising a first flexible interconnect structure having a first layer, a second layer and a dielectric material separating the first layer from the second layer, wherein the first layer comprises one or more first interconnection regions that are configured to contact one or more first conductive features formed on a substrate surface of the first solar cell substrate and the second layer comprises one or more second interconnection regions that are configured to contact one or more second conductive features formed on the substrate surface, and wherein the first solar cell substrate has an n-type region that is in communication with the one or more first conductive features and a p-type region that is in communication with the one or more second conductive features.

Embodiments of the present invention may also provide a method of forming a solar cell device, comprising receiving a flexible interconnect structure having a first layer, a second layer and a dielectric material separating the first layer from the second layer, wherein a portion of the first layer and a portion of the second layer are in contact with a first surface of the flexible interconnect structure, and positioning the flexible interconnect structure over a solar cell substrate so that the portion of the first layer is in electrical communication with an n-type region disposed on a solar cell substrate and the portion of the second layer is in electrical communication with a p-type region disposed on a solar cell substrate.

Embodiments of the present invention may also provide a method of forming a solar cell device, comprising forming an enclosed region between one or more walls of an enclosure and an interconnect structure, where in the interconnect structure comprises a first layer, a second layer, a dielectric material disposed between the first layer and the second layer, and a first hole and a second hole that are each in communication with the enclosed region and are formed through a portion of the interconnect structure, positioning a first conductive feature formed on a solar cell substrate adjacent to the first layer, and a second conductive feature formed on the solar cell substrate adjacent to the second layer, wherein the first conductive feature is in electrical communication with an n-type region formed on the solar cell substrate and the second conductive feature is in electrical communication with a p-type region formed on the solar cell substrate, heating the first conductive feature, the first layer, the second conductive feature and the second layer so that a bond is formed between the first conductive feature and the first layer and the second conductive feature and the second layer, and urging the first conductive feature against the first layer and the second conductive feature against the second layer during the heating process.

Embodiments of the present invention may also provide a method of forming a solar cell device, comprising forming a solar cell substrate having an n-type region and a p-type region that form part of a junction that is adapted to convert light into electrical energy, wherein the n-type region is in electrical communication with a first conductive feature disposed on a surface of the solar cell substrate and the p-type region is in electrical communication with a second conductive feature disposed on the surface, depositing a first compliant layer over the first conductive feature and the second conductive feature, wherein the first complaint layer has a first hole and a second hole formed therein, depositing a conductive material in the first hole and the second hole, wherein the conductive material disposed in the first hole is in electrical communication with the first conductive feature and the conductive material disposed in the second hole is in electrical communication with the second conductive feature, and positioning an interconnect structure having a first layer, a second layer, and a dielectric material separating the first layer from the second layer over a surface of the first compliant layer so that the first layer is in electrical communication with the first conductive feature through the first conductive material disposed in the first hole, and the second layer is in electrical communication with the second conductive feature through the first conductive material disposed in the second hole.

Embodiments of the present invention may also provide a plurality of interconnected solar cells, comprising a first solar cell assembly comprising a first solar cell substrate having an n-type region and a p-type region that are part of a junction, or solar cell junction, that is adapted to convert light into electrical energy, wherein the n-type region is in electrical communication with a first conductive feature disposed on a surface of the first solar cell substrate and the p-type region is in electrical communication with a second conductive feature disposed on the surface, and a first flexible interconnect structure having a first layer, a second layer and a dielectric material separating the first layer from the second layer, wherein the first layer is in electrical communication with the first conductive feature formed on the first solar cell substrate and the second layer is in electrical communication with a second conductive feature formed on the first solar cell substrate, and a second solar cell assembly comprising a second solar cell substrate having an n-type region and a p-type region that are part of a solar cell junction that is adapted to convert light into electrical energy, wherein the n-type region is in electrical communication with a first conductive feature disposed on a surface of the second solar cell substrate and the p-type region is in electrical communication with a second conductive feature disposed on the surface, and a second flexible interconnect structure having a first layer, a second layer and a dielectric material separating the first layer from the second layer, wherein the first layer is in electrical communication with the first conductive feature formed on the second solar cell substrate and the second layer is in electrical communication with a second conductive feature formed on the second solar cell substrate, wherein the first layer in the first flexible interconnect structure is electrically connected to the first layer or the second layer of the second flexible interconnect structure.

Embodiments of the present invention may also provide a method of forming a solar cell array, comprising forming two or more solar cell assemblies that each comprise a solar cell substrate having an n-type region and a p-type region that are part of a solar cell junction that is adapted to convert light into electrical energy, wherein the n-type region is in electrical communication with a first conductive feature disposed on a surface of the solar cell substrate and the p-type region is in electrical communication with a second conductive feature disposed on the surface, and a flexible interconnect structure having a first layer, a second layer and a dielectric material separating the first layer from the second layer, wherein the first layer is in electrical communication with the first conductive feature and the second layer is in electrical communication with a second conductive feature, and placing a first layer in a flexible interconnect structure in one of the two or more solar cell assemblies in contact with either a first layer or a second layer of a flexible interconnect structure in another of the two or more solar cell assemblies.

Embodiments of the present invention may also provide a method of forming a solar cell device, comprising forming a solar cell substrate having an n-type region and a p-type region that are part of a solar cell junction that is adapted to convert light into electrical energy, wherein the n-type region is in electrical communication with a first conductive feature disposed on a surface of the solar cell substrate and the p-type region is in electrical communication with a second conductive feature disposed on the surface, positioning an interconnect structure having a first layer, a first hole formed through the first layer, a second layer, a second hole formed through the second layer and a dielectric material separating the first layer from the second layer against the surface of the solar cell substrate so that the first layer is in electrical communication with the first conductive feature and the second layer is in electrical communication with a second conductive feature, and depositing a conductive material in the first hole and the second hole so that the conductive material creates a first conductive path between the first layer and the first conductive feature, and a second conductive path between the second layer and the second conductive feature.

Embodiments of the present invention may also provide a method of forming a solar cell device, comprising forming a solar cell substrate having an n-type region and a p-type region that are part of a solar cell junction that is adapted to convert light into electrical energy, wherein the n-type region is in electrical communication with a first conductive feature disposed on a surface of the solar cell substrate and the p-type region is in electrical communication with a second conductive feature disposed on the surface, depositing a conductive material on two or more regions of the first conductive feature and on two or more regions of the second conductive feature, wherein each of the two or more regions of conductive material deposited on the first conductive feature are at least a first distance from each of the two or more regions of conductive material deposited on the second conductive feature, and positioning a flexible interconnect structure having a first layer, a second layer and a dielectric material, separating the first layer from the second layer, over the conductive material deposited on the first and second conductive features so that an electrical connection is formed between the first layer and the first conductive feature and the second layer and the second conductive feature.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIGS. 1A-1B illustrate schematic cross-sectional views of examples of solar cell devices that may be used with one embodiments of the invention described herein.

FIG. 2 illustrates a schematic cross-sectional view of a solar cell according to embodiments of the invention.

FIGS. 3A-3B schematically illustrates an interconnecting structure and supporting hardware during different phases of a bonding process according to embodiments of the invention.

FIG. 4 schematically illustrates a plan view of an interconnecting structure according to embodiments of the invention.

FIG. 5A schematically illustrates a cross-sectional isometric view of an interconnecting structure according to embodiments of the invention.

FIG. 5B schematically illustrates a plan view of an interconnecting structure according to embodiments of the invention.

FIG. 5C a cross-sectional isometric view of an interconnecting structure according to embodiments of the invention.

FIG. 5D schematically illustrates a solar cell electrical connection schematic according to embodiments of the invention.

FIG. 5E a cross-sectional isometric view of an interconnecting structure according to embodiments of the invention.

FIG. 6A schematically illustrates a cross-sectional isometric view of an interconnecting structure according to embodiments of the invention.

FIG. 6B schematically illustrates a cross-sectional view of the interconnecting structure illustrated in FIG. 6A after bonding according to embodiments of the invention.

FIG. 7 schematically illustrates a cross-sectional isometric view of an interconnecting structure according to embodiments of the invention.

FIG. 8 illustrates a flow chart of methods used to bond a solar cell substrate to an interconnecting structure according to an embodiment of the invention.

FIGS. 9A-9B schematically illustrates an interconnecting structure and supporting hardware during different steps of a bonding process according to embodiments of the invention.

FIGS. 10A-10B schematically illustrates an interconnecting structure and supporting hardware during different steps of a bonding process according to embodiments of the invention.

FIG. 11A is a side view of an array or interconnected solar cells according to embodiments of the invention.

FIG. 11B schematically illustrates an electrical connection configuration of an array or interconnected solar cells according to embodiments of the invention.

FIG. 11C a cross-sectional isometric view of an interconnecting structure according to embodiments of the invention.

FIG. 11D is a side view of an array or interconnected solar cells according to embodiments of the invention.

FIG. 12A schematically illustrates a plan view of an interconnecting structure according to embodiments of the invention.

FIG. 12B schematically illustrates a side cross-sectional isometric view of an interconnecting structure according to embodiments of the invention.

FIGS. 13A-13N illustrate schematic cross-sectional views of a solar cell during different stages in a sequence according to one embodiment of the invention.

FIG. 14 illustrates a flow chart of methods to metalize a solar cell according to embodiments of the invention.

FIG. 15A schematically illustrates a plan view of a patterned dopant formed on a surface of the substrate according to embodiments of the invention.

FIG. 15B schematically illustrates a close-up plan view of a portion of the substrate surface illustrated in FIG. 15A according to embodiments of the invention.

FIG. 16 schematically illustrates a plan view of a patterned insulating material formed on a surface of the substrate according to embodiments of the invention.

FIG. 17 schematically illustrates a plan view of an interconnecting structure according to embodiments of the invention.

For clarity, identical reference numerals have been used, where applicable, to designate identical elements that are common between figures. It is contemplated that features of one embodiment may be incorporated in other embodiments without further recitation.

### DETAILED DESCRIPTION

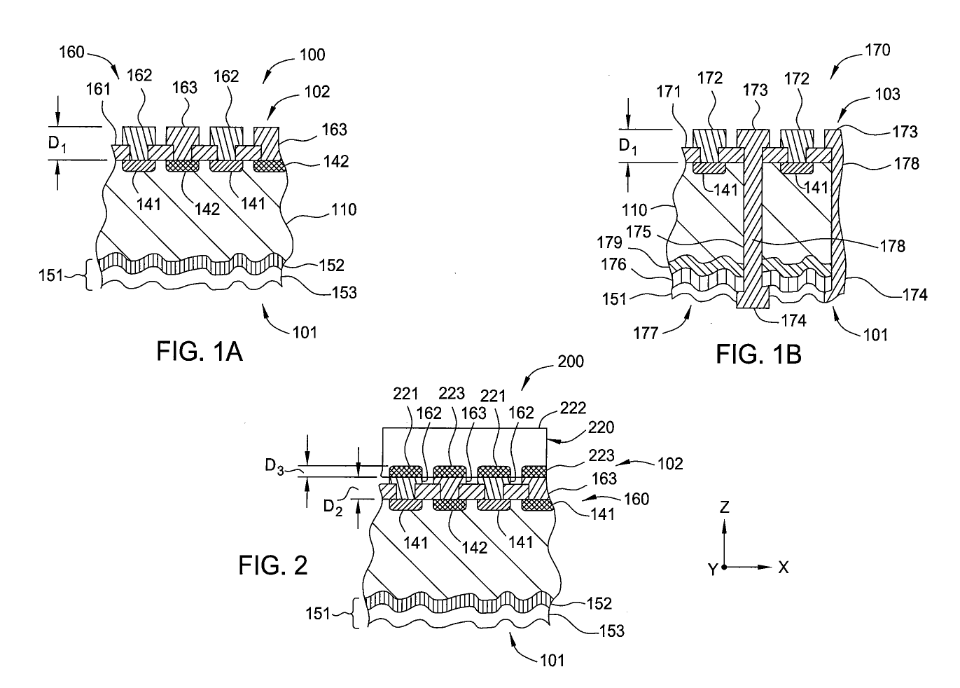

Embodiments of the invention contemplate the formation of a high efficiency solar cell using a novel processing sequence to form a solar cell device. In one embodiment, the methods include the use of a pre-fabricated back plane that is bonded to the metalized solar cell device to form an interconnected solar cell device that can be easily electrically connected to external components used to receive the generated electricity. Typical external components may include an electrical power grid, satellites, electronic devices or other similar power requiring units. Solar cell structures (e.g., substrate 110 in FIGS. 1-7) that are particularly benefited from the invention include all back contact solar cells, such as those in which both positive and negative contacts are formed only on the rear surface of the device. Active regions may contain organic material, single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CuInSe₂), gallilium indium phosphide (GaInP₂), as well as heterojunction cells, such as GaInP/GaAs/Ge, ZnSe/GaAs/Ge or other similar substrate materials that can be used to convert sunlight to electrical power. In one embodiment, it is desirable to utilize a pre-fabricated back plane that is more flexible than the substrate to which it is attached to minimize the amount of stress created by the interconnection or attachment process(es), such as the ones discussed herein.

FIG. 1A is a cross-sectional side view of a solar cell device 100 that illustrates an interconnecting structure 160 formed on a surface 102 of the solar cell device 100. In one example, as shown in FIG. 1A, the solar cell device 100 is an all backside contact solar cell structure in which light is first received on the front surface 101 side of the solar cell device 100. In general, interconnecting structure 160 in the formed solar cell device 100 contains a patterned array of conductive features 162, 163 that are electrically connected to desired portions of the solar cell device 100 and are designed to carry the generated current when the solar cell is exposed to sunlight. In one example, the solar cell device 100 comprises a substrate 110, a dielectric layer 161 (e.g., silicon dioxide), conductive features 162 and 163, and an antireflection layer 151. In this configuration, the conductive features 162, 163 are formed over the dielectric layer 161 disposed on the surface 102 and are each in electrical communication with active regions formed in the substrate 110. In one embodiment, the dielectric layer 161 is a silicon dioxide layer that is between about 50 Å and about 3000 Å thick. In one example, the conductive feature 162 is in electrical contact with a p-type doped region 141 and the conductive feature 163 is in electrical contact with an n-type doped region 142, which are both formed in the substrate 110 and used to form portions of the active solar cell device. In one configuration, the antireflection layer 151 comprises a thin passivation/antireflection layer 152 (e.g., silicon oxide, silicon nitride layer). In general, the p-type doped region 141 may comprise a dopant atom selected from the group consisting of boron (B), aluminum (Al), or gallium (Ga) and the n-type doped region 142 comprise a dopant atom selected from the group consisting of phosphorous (P), arsenic (As), or antimony (Sb). In another configuration, the antireflection layer 151 comprises a thin layer 153 comprising amorphous silicon (a-Si:H), or a thin layer 153 comprising amorphous silicon carbide (a-SiC:H) and silicon nitride (SiN) 154 stack, that is formed on the front surface 101 using a conventional chemical vapor deposition (PECVD) technique.

FIG. 1B is a cross-sectional side view of a solar cell 103 that illustrates an interconnecting structure 170 formed on a pin-up module type solar cell module, or PUM solar cell device. The PUM type structures typically contain a plurality of holes 175 that are formed through the substrate 110 and serve as vias for the interconnection of the top contact structure 177 to a conductive features 173 by use of the conductive pins 178. Light is received from the by the solar cell 103 through the top contact structure 177 formed on the front surface 101 of the solar cell 103. In general, interconnecting structure 170 in the formed solar cell 103 contains a patterned array of conductive features 172, 173 that formed on back of the substrate 110 to simplify the electrical connection structure to external solar collector components. In one example, the solar cell 103 comprises a substrate 110 comprising a p-type base region, dielectric layer 171, interconnecting structure 170, an n-type doped region 179, optional transparent conductive oxide (TCO) layer 176, and antireflection layer 151 (discussed above). In this configuration, the conductive features 172, 173 are formed over the dielectric layer 171 (e.g., similar to the dielectric layer 161) disposed on the surface 102, and are each in electrical communication with portions of the active regions formed in the substrate 110. In one example, the conductive feature 172 is in electrical contact with a p-type doped region 141 formed in the p-type base region of the substrate 110 and the conductive feature 173 is in electrical contact with an n-type doped region 179 through the pins 178, front contact 174, and TCO layer 176. In general, the p-type doped region 174 may comprise a dopant atom selected from the group consisting of boron (B), aluminum (Al), or gallium (Ga) and the n-type doped region 179 comprise a dopant atom selected from the group consisting of phosphorous (P), arsenic (As), or antimony (Sb).

The patterned metal structures found in the solar cell device 100 or solar cell 103, such as the conductive features 162, 163, conductive features 172, 173, pins 178, and front contact 174 are generally a conductive material that is either integrally formed or deposited on a surface the substrate 110 by use of a PVD, CVD, screen printing, electroplating, evaporation or other similar deposition technique. The patterned metal structures may contain a metal, such as aluminum (Al), silver (Ag), copper (Cu), tin (Sn), nickel (Ni), zinc (Zn), titanium (Ti), tantalum (Ta), or lead (Pb). In some cases copper (Cu) may be used as a second layer, or subsequent layer, that is formed on a suitable barrier layer (e.g., TiW, Ta, etc.) that prevents diffusion of the copper material into undesirable regions of the substrate 110. While FIGS. 1A and 1B illustrate only two types of solar cell device structures these configurations are not intended to be limiting as to the scope of the invention described herein, since other configurations could be used without deviating from the basic scope of the invention described herein.

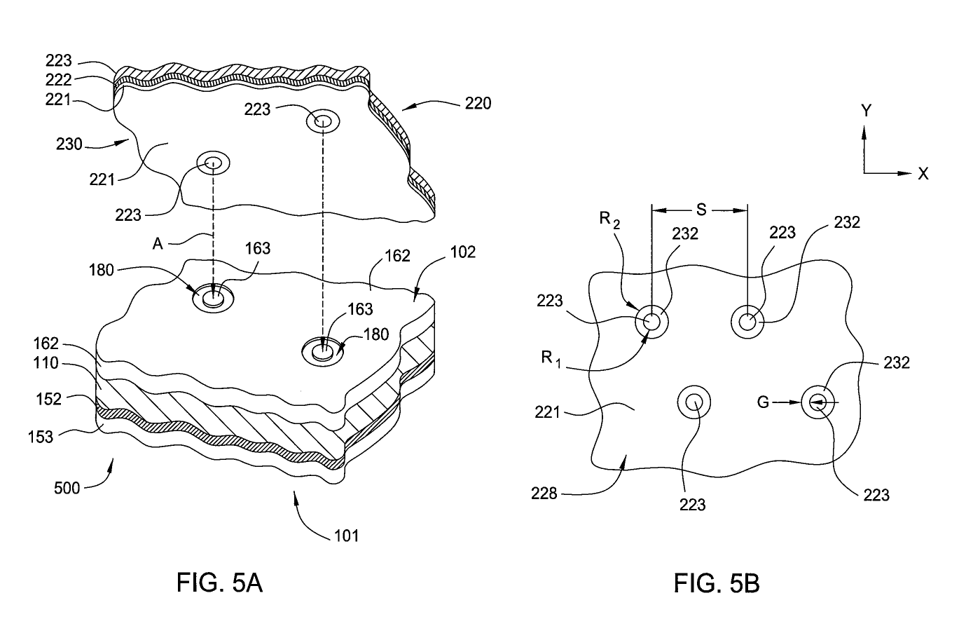

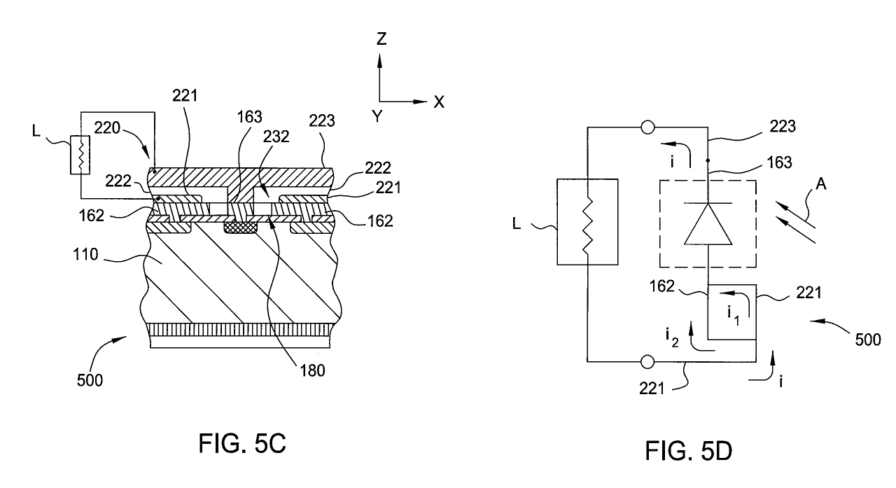

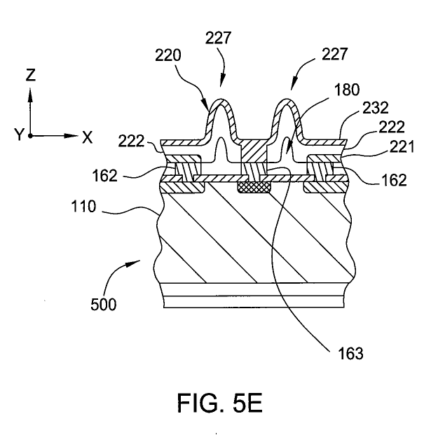

In one embodiment, the conductive features 162, 163 or conductive features 172, 173 are formed by patterning a blanket deposited conductive layer to electrically isolate desired regions of the substrate 110 to form the interconnecting structure 160 or 170. In one embodiment, a blanket layer is first deposited over the surface 102 of the substrate 110 and then the conductive features 162, 163 or 172, 173 are formed by removing portions of the blanket layer, or isolating channels (e.g., reference numeral 180 in FIG. 5A), by one or more laser ablation, lithographic patterning and wet or dry etching, or other similar techniques. In general, it is desirable to form or align the isolating channels so that separate and electrically isolated connection structures can be formed to separately connect all of the p-type regions and all of the n-type regions of the solar cell device. An example of a solar cell formation process that can be adapted to form a solar cell device having a desirably formed interconnect structure is further described in the U.S. Provisional Patent Application Ser. No. 61/139,423 [Atty. Dkt. # APPM 13437L03], filed Dec. 19, 2008, and U.S. Provisional Patent Application Ser. No. 61/121,537 [Atty. Dkt. # APPM 13438L02], filed Dec. 10, 2008, which are both incorporated by reference herein in their entirety.

In more conventionally formed solar cell structures, such as is illustrated in FIGS. 1A-1B, the current carrying conductive features 162, 163 or conductive features 172, 173 are generally each formed to a thickness D₁ that has a low enough series resistance to allow the efficient transfer of the generated current to the external power collecting devices outside the formed solar cell 100 or 103. Typically the thickness D₁ of the more conventionally formed solar cell 100, 103 is about 50,000 to about 100,000 angstroms (Å). Therefore, since typical maximum deposition rates for most PVD, CVD, electroplating or other similar deposition processes is on the order of 10,000 Å/minute the process of forming the conductive features 162, 163 or conductive features 172, 173 can be on order of 5 to 10 minutes. The significant time that it takes to form the conductive features 162, 163 or conductive features 172, 173 can impact the cost-of-ownership (CoO) of the solar cell manufacturing process and the unit cost for each formed solar cell device. Also, since the typical deposition processes used to form the conductive features are typically performed at moderate to high temperatures, and the coefficient of thermal expansion difference between the substrate 110 and the typical metallic elements used to form these layers can be large, the intrinsic stress (e.g., internal stress in the deposited layer) and extrinsic stress (e.g., stress created by thermal mismatch) created in the formed solar cell device can cause the substrate to deform, and the electrical contact between the substrate 110 and the deposited metal to degrade or become electrically disconnected (e.g., “open circuit”). Therefore, there exists a need for improved methods of forming a solar cell device that can be formed in less time, at a reduced overall production cost, and have a reduced overall stress in the formed solar cell device. It should be noted that the magnitude of the force, and thus deformation of the substrate, created by the intrinsic stress is believed to vary as a function of the thickness of the deposited conductive features 162, 163 or 172, 173 layers.

### Interconnect Structures

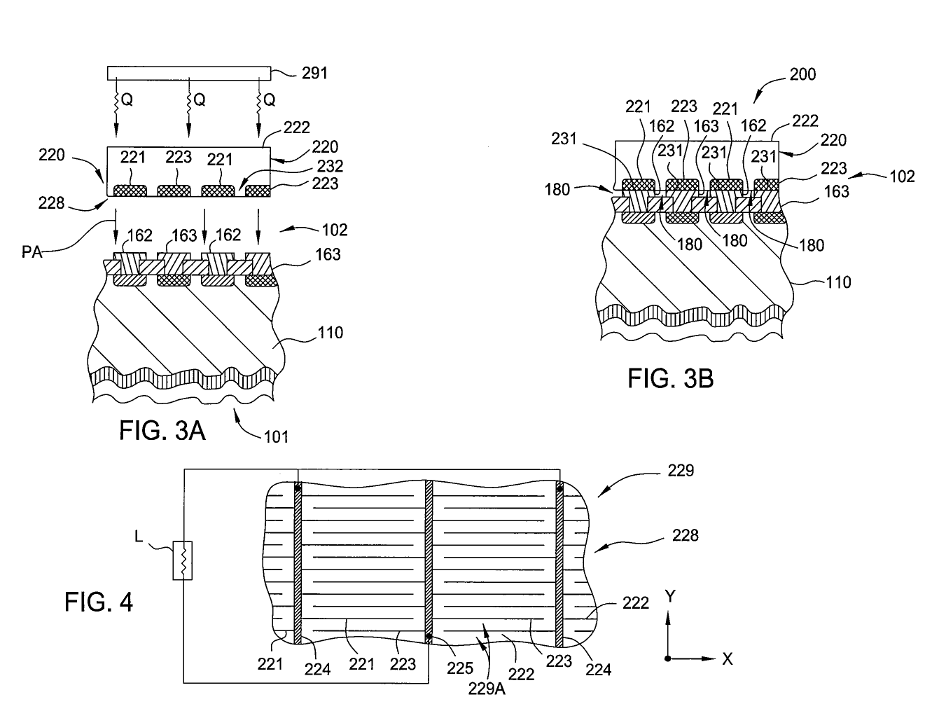

FIG. 2 schematically illustrates one embodiment of an external interconnect structure 220 that can be used to interconnect portions of a solar cell 200 by reducing the time required to form the conductive components in an interconnecting structure 160 formed on the solar cell 200. In one example, the interconnecting structure formed on the substrate is similar to the structures discussed above in conjunction with reference numerals 160 illustrated in FIG. 1A. As illustrated in FIG. 2, the external interconnect structure 220 is bonded to the interconnecting structure 160, and thus all of the desired electrical interconnections on at least one side of the solar cell are formed to create an interconnected solar cell device. In general, the use of an external interconnect structure 220 can help to improve substrate throughput in the solar cell formation processing sequence by allowing the interconnect structure 220 and interconnecting structure 160 to be formed in separate parallel processes. Use of an external interconnect structure 220 can also help reduce the intrinsic or extrinsic stress created in the thin solar cell substrates by reducing the required thickness of the deposited conductive features 162, 163, or conductive features 172, 173, on the surface of the substrate. The stress induced in a formed solar cell device by the conductive features can be minimized by reducing their required deposited film thickness, thus improving the substrate throughput and the device yield of the solar cell formation process. Also, by minimizing the required thickness of the layer(s) used to form the conductive features (e.g., reference numerals 162, 163, or 172, 173), the amount of energy or chemicals required to ablate or etch through the deposited layer(s) used to form these conductive patterned regions is reduced, thus minimizing possible damage to the substrate. Moreover, other more cost effective patterning techniques such as ink jet or screen printing can be used to mask or directly deposit the conductive features, since the amount of deposited metal required is much less than in conventionally formed structures since the primary current path is through the conductive regions in the external interconnect structure 220. While FIGS. 2 and 3A-3B use an all back contact type solar cell device (e.g., FIG. 1A) to illustrate various different embodiments of the invention, this configuration is not intended to limiting as to the scope of the invention described herein.

In one embodiment, the external interconnect structure 220 generally contains a patterned metal structures 221, 223 that is disposed on, integrated within, or bonded to a substrate 222. In one embodiment, the substrate 222 is a flexible element that supports the patterned metal structures 221, 223 and allows the external interconnect structure 220 to conform to the shape of the interconnecting structure 160 formed on the solar cell 200 when it is attached. In one example, the substrate 222 is a compliant piece of polymeric material, such as a sheet of a polyimide material, or other similar materials. In general, the external interconnect structure 220 is designed to carry the bulk of the generated current when the solar cell 200 is exposed to sunlight. In one embodiment, the conductive features 162, 163 or conductive features 172, 173 are formed to a desirable thickness D₂ that is generally thinner than the conventional thickness D₁ (FIGS. 1A-1B) to reduce the stress in the formed solar cell, reduce the material cost, and the time required to form the conductive features 162, 163, or 172, 173. In general, in the configuration illustrated in FIG. 2 the series resistance of the conductive features 162, 163 or conductive features 172, 173 formed in the solar cell 200 would be too high without the use of the patterned metal structures 221, 223 that has a thickness D₃. In one embodiment, the thickness D₂ plus thickness D₃ equals the thickness D₁ found in a more conventionally formed structure. In one embodiment, the thickness D₂ of the conductive features 162, 163 or conductive features 172, 173 is about 500 Å to about 50,000 Å, and the thickness D₃ of the patterned metal structures 221, 223 is about 20,000 Å to about 500,000 Å to allow the efficient transfer of the generated current to external devices outside the formed solar cell 200. In one example, the thickness D₂ of the conductive features 162, 163 or conductive features 172, 173 is between about 50 Å to about 5,000 Å. It should be noted that the stress generated in the formed solar cell by the deposited thin conductive features and bonding of the external interconnect structure 220 to the substrate 110 will primarily be in the x-y plane (FIG. 2) parallel to the surface 102, and thus the overall stiffness of the external interconnect structure 220 in any direction found on a plane containing the x-y directions can be reduced by controlling its thickness, the materials used, or the geometric shape (see FIG. 5E) of the structure. In one example, the geometric shape of the external interconnect structure 220 is configured so that it is substantially non-flat relative to the x-y plane, such as by adding a feature 227 (FIG. 5E), such as a flexible accordion shaped region, bump or other shaped feature that reduces the external interconnect structure's stiffness in the x and/or y-directions. The addition of the features 227 that are non-flat relative to the x-y plane can help improve the bending stiffness (i.e., loads supplied normal to the x-y plane) and thus reduce the likelihood that the substrate 110 will warp.

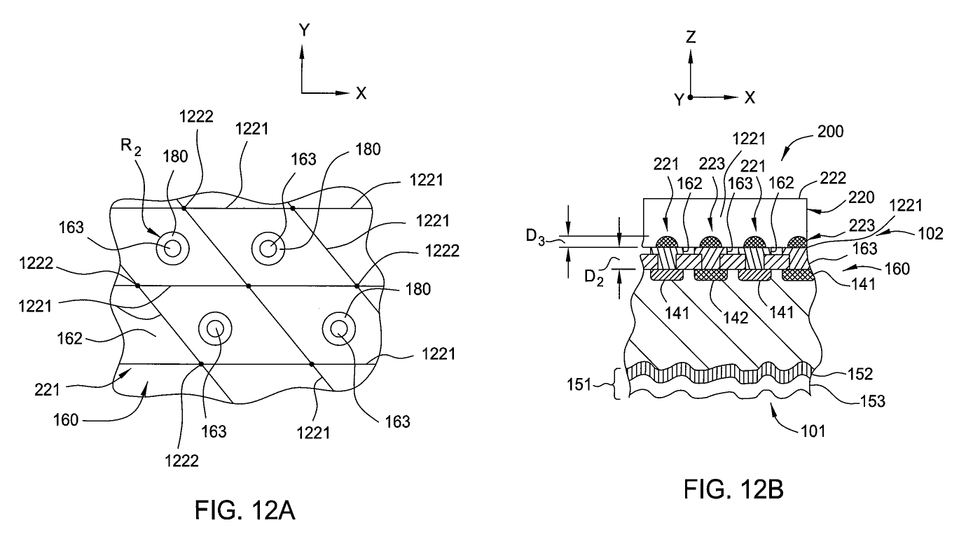

The patterned metal structures 221, 223 are generally formed from a conductive material that is either integrally formed or deposited on a surface the substrate 222 by use of a PVD, CVD, screen printing, electroplating, evaporation or other similar deposition technique. The patterned metal structures 221, 223 may contain a metal, such as aluminum (Al), copper (Cu), silver (Ag), tin (Sn), nickel (Ni), zinc (Zn), gold (Au), or lead (Pb). In one embodiment, the patterned metal structures 221, 223 may be formed from a conductive polymer material, such as a conductive epoxy. In one embodiment, the patterned metal structures 221, 223 are each made of a thin metal foil or sheet like material. In another embodiment, the patterned metal structures 221, 223 are each made of a wire mesh like material (e.g., FIGS. 12A-12B).

In one embodiment, the substrate 222 is a printed circuit board material, such as a material like polytetrafluoroethylene, FR-4, FR-1, CEM-1, CEM-3 or other similar material. In one embodiment, the substrate 222 is a sheet of material that may be selected from the group consisting of polyethylene terephthalate (PET), polyimide, nylon, polyvinyl chloride (PVC), or other similar polymeric or plastic materials. In one example, the substrate 222 comprises an insulating material that is laminated together with an epoxy resin, and the patterned metal structures 221, 223 are made from a copper foil material.

FIGS. 3A and 3B schematically illustrate a process of interconnecting the external interconnect structure 220 with the patterned metal structures 221, 223 formed on a surface of the substrate 110. As shown in FIGS. 3A and 3B, the external interconnect structure 220 formed on surface 228 is bonded to the interconnecting structure 160 by first positioning the external interconnect structure 220 on the interconnecting structure 160 and then applying enough heat “Q” to cause the conductive parts of the patterned metal structures 221, 223 to form a bond with the interconnecting structure 160. In one embodiment, a solder type material is disposed between a surface of the patterned metal structures 221, 223 or the interconnecting structure 160 to form a reliable electrical contact between these components. In one embodiment, the electrical interconnections formed between the external interconnect structure 220 and the interconnecting structure 160 include a plurality of discrete interconnecting regions on each of the patterned metal structures 221, 223 that form an electrical connection to adjacent regions found on the respective conductive features 162, 163. During the bonding process, as shown in FIG. 3A, the external interconnect structure 220 is positioned “PA” on the solar cell substrate 110 so that when the external interconnect structure 220 and the interconnecting structure 160 are aligned and desirably bonded together (FIG. 3B). In one embodiment, a heated application device 291, such as a heating element (e.g., soldering iron) is placed in thermal communication with patterned metal structures 221, 223 to cause a conductive material 231 disposed at the interface between the patterned metal structures 221, 223 and the interconnecting structure 160 to melt and form an electrical connection there-between. In one configuration, the conductive material 231 is deposited on the exposed surface of the patterned metal structures 221, 223 or the interconnecting structure 160 before heat “Q” is applied to the contacting elements. In one embodiment, the deposited conductive material 231 is a solder type material that may contain a metal, such as tin (Sn), silver (Ag), copper Cu, nickel (Ni), zinc (Zn), indium (In), bismuth (Bi) and/or lead (Pb).

FIG. 4 is a schematic plan view of one embodiment of an interdigitated interconnect structure 229 formed on a surface 228 of the external interconnect structure 220. In this configuration, the interdigitated interconnect structure 229 has separate patterned metal structures 221, 223 that are each formed into interdigitated finger 229A shaped structures that are separately connected to the n-type regions and the p-type regions of a solar cell device. In one embodiment, as shown in FIG. 4, each of the interdigitated fingers 229A are either connected to a first busline 224 or a second busline 225. In this configuration, each of the buslines 224, 225 are sized to collect the current passing from each of their connected interdigitated fingers 229A and deliver the collected current to the driven external load “L” outside the formed solar cell device during operation.

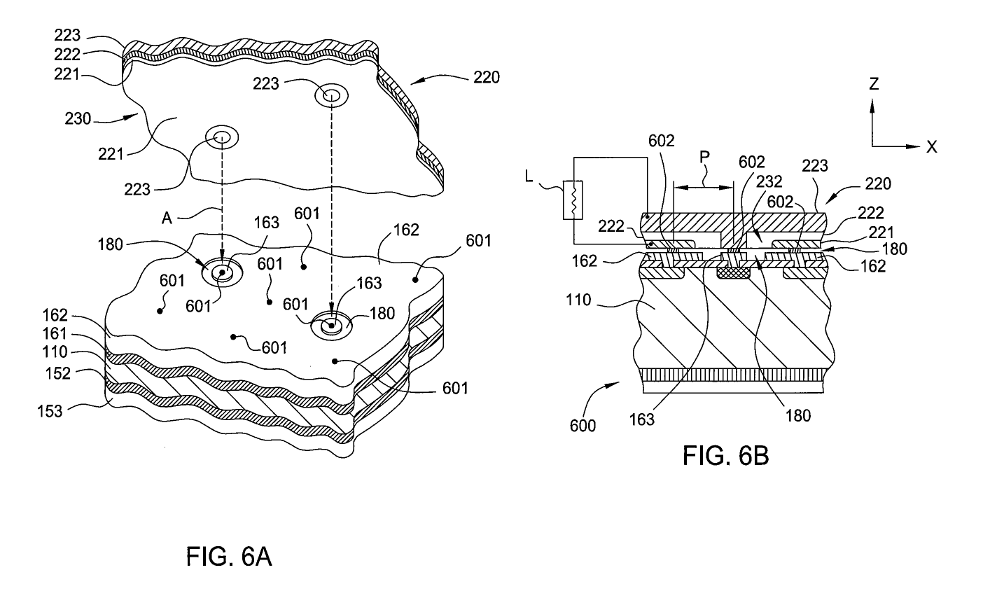

FIGS. 5A-5C illustrate one embodiment of an arrayed interconnect structure 230 formed on a surface 228 on the external interconnect structure 220. The arrayed interconnect structure 230 is configured to mate with the conductive features formed on the surface of the substrate, such as conductive features 162, 163 formed on a surface of the substrate 110. In one configuration, as shown in FIG. 5A, the patterned metal structures 221, 223 formed on an external interconnect structure 220 are configured so that they can be separately connected to the conductive features 162, 163 found on the surface 102 of the substrate 110. FIG. 5B is a plan view illustrating an array of electrically isolated patterned metal structures 221, 223 formed on a surface 228 of the external interconnect structure 220. The patterned metal structures 223 can be electrically isolated from the patterned metal structure(s) 221 by an insulating region 232 formed in the external interconnect structure 220. Referring to FIG. 5C, in one embodiment, the insulating region 232 comprises a portion of the substrate 222 that is configured to electrically isolate the patterned metal structures 221 and 223. In one embodiment, the insulating region 232 is simply a region that forms an air gap 180 (FIGS. 3B and 6B) between the patterned metal structures 221 and 223. In one example, the insulating region 232 is an annular region, or gap “G,” formed between a patterned metal structure 223 having an outer radius of R₁ and a patterned metal structure 221 having an inside radius of R₂. The gap “G” can thus be defined as being equal to R₂ minus R₁. In one embodiment, the array of the electrically isolated patterned metal structures 223 found in the arrayed interconnect structure 230 has a nearest neighbor distance equal to spacing “S” between centers. In one example, the arrayed interconnect structures 230 have a radius R₁ that is between about 125 micrometers (μm) and about 1000 μm, a gap “G” that is between about 100 μm and about 1 mm and a nearest neighbor spacing “S” that is less or equal to about 2 mm.

Referring to FIGS. 5A-5B, in one configuration the conduction of the generated current by the formed and externally connected solar cell 500 will pass through the conductive features 163 to the patterned metal structure 223, while a portion of the generated current provided to the patterned metal structure 221 by the conductive features 162 will flow in parallel through the conductive feature 162 and the patterned metal structure 221. In one example, as schematically illustrated in FIG. 5D, the current “i” generated by the light “A” striking the solar cell 500 flows through the conductive features 163, the patterned metal structure 223, the external load “L”, and a portion of the patterned metal structure 221 before it splits into a current “i₁” that flows through the patterned metal structure 221 and a current “i₂” that flows through the conductive features 162. The split currents “i₁” and “i₂” are then collected by the conductive features 162 and returned to the p-type side of the formed device. In this configuration, it is generally desirable to minimize the required thickness of the conductive features 162 to reduce the solar cell formation process time and cost-of-ownership (CoO) thus assuring that the generated current primarily flows through the patterned metal structure 221 rather than through the conductive features 162, or current “i₂” is greater than current “i₁”. Minimizing the required thickness of the conductive features 162 is generally desirable since it will reduce the conductive features 162 deposition material consumable cost, capital equipment costs, processing time and/or solar cell fabrication space. Also, it is believed that the external interconnect structure 220 can be inexpensively made in an environment that does not require the same processing controls required to form the solar cell device (e.g., thermal budget, contamination) and allow the use of inexpensive formation processes and materials that may not be compatible with the typical solar cell formation process, such as annealing, diffusion or deposition steps.

In one embodiment, the array of the electrically isolated patterned metal structures 221, 223 found in the arrayed interconnect structure 230 are formed in a hexagonal close pack (HCP) array in which each of the patterned metal structures 223 have six nearest neighbors that are spaced a distance equal to spacing “S” apart within a field of the patterned metal structure 221 (FIG. 5B). In another embodiment, the array of electrically isolated patterned metal structures 223 are formed in a simple rectangular array pattern or other array pattern having some short or long range order within the field of the patterned metal structure 221. By carefully selecting a desirable pattern or spacing of the patterned metal structures 221 and 223 in the arrayed interconnect structure 230 the solar cell resistance and solar cell efficiency can be optimized. The required spacing and surface area of the patterned metal structures 221, 223 will generally depend on the bulk resistance of the substrate 110 and the conductivity and thickness of the metal used to form the patterned metal structures 221, 223 and conductive features (e.g., reference numerals 162, 163). An arrayed interconnect structure 230 has advantages over conventional interdigitated structures, since the arrayed pattern in the interconnect structure 230 does not require the generated current to flow along the length of each of the interdigitated fingers (e.g., fingers 229A) found in an interdigitated interconnect structure, thus shortening the resistive path that the current flows through. The path through which the current flow in the arrayed interconnect structure 230 is shorter than the path through an interdigitated structure thus improving the solar cell's collection efficiency. For example, referring to FIGS. 4 and 5A-5B, the current flowing through the fingers 229A must flow in the x-direction and then flow through the buslines 224, 225, which are aligned along the y-direction before it can be delivered to the external load “L,” whereas the current flowing through the patterned metal structures 221 and 223 shown in FIGS. 5A-5B can flow in the x-direction and y-directions as needed. It should also be noted that the current flow region (i.e., surface area times layer thickness) in the metal structures through which the current flows in an interdigitated interconnect structure is limited by the spacing of the contact areas on the surface 228 that are required to make reliable contact with the various n-type or p-type regions of the substrate.

FIGS. 6A and 6B illustrate another configuration of the external interconnect structure 220 in which the conductive features, such as conductive features 162, 163 are electrically connected to the patterned metal structures 221 and 223 by a plurality of formed connection regions 602 (FIG. 6B) that interconnect the solar cell 600. In one configuration, as shown in FIG. 6A, the patterned metal structures 221, 223 formed on an external interconnect structure 220 are configured so that they can be separately connected to the conductive features 162, 163 found on the surface 102 of the substrate 110. In one embodiment, an array of solder material 601 (FIG. 6A) are disposed between the external interconnect structure 220 and the conductive features 162, 163 in a desirable pattern. The solder material 601 may comprise a ball of solder material that is positioned on external interconnect structure 220 or on the conductive features 162, 163 by use of an inkjet printing process, manually placement process, screen printing process, or other similar process. FIG. 6B is a side cross-sectional view illustrating a solar cell structure in which the external interconnect structure 220 and the conductive features 162, 163 are bonded together by the connection regions 602 using a process similar to the one discussed above in conjunction with FIGS. 3A-3B. In this configuration, the solder material 601 found in the connection regions 602 form conductive paths through which the current generated by the solar cell 600 can pass to the external load “L”. The solder material 601 may contain a metal, such as tin (Sn), silver (Ag), copper Cu, nickel (Ni), zinc (Zn), indium (In), bismuth (Bi) and/or lead (Pb).

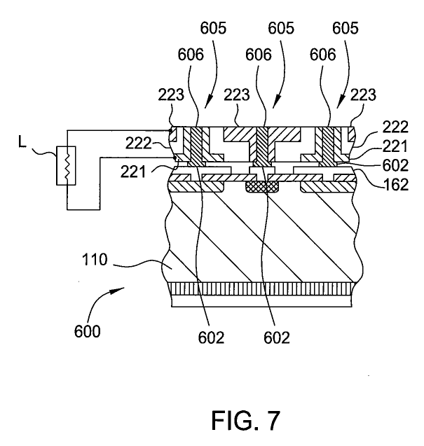

While FIGS. 6A-6B and 7, illustrate an arrayed interconnect structure 230 to describe some of the various embodiments of the present invention, this configuration is not intended to limiting as to the scope of the invention described herein. One skilled in the art will appreciate that a bonded interconnecting structure could also be formed between conductive features 162, 163 and patterned metal structures 221, 223 that are configured in an interdigitated pattern (FIG. 4). In an interdigitated pattern type configuration, the formed connection regions 602 may be aligned a linear array, staggered pattern or random pattern along each of the fingers 229A and/or buslines 224, 225 to connect the conductive features 162, 163 and patterned metal structures 221, 223.

A formed solar cell 600 having discrete bonded regions, or connection regions 602, has some advantages over more conventional configurations in which large portions of the patterned metal structures 221, 223 are bonded to the conductive features 162, 163. In one example, the stress generated in the formed solar cell 600 can be reduced versus more conventional configurations by allowing the external interconnect structure 220 and/or substrate 110 to deform due to the stress during processing. The relaxed stress due to the deformation of the external interconnect structure 220 and/or substrate 110, thus reduces the likelihood that the generated extrinsic or intrinsic stress created during processing in either of the components, or between the two components, will affect the solar cell fabrication process device yield or the average solar cell lifetime. In one embodiment, it is desirable to size the cross-section of the external interconnect structure 220 so that it will primarily bend or distort under the stress applied to it through the connection regions 602. Therefore, it is generally desirable control the overall thickness, layer thickness, geometric shape, and materials from which the patterned metal structures 221, 223 and substrate 222 are made, so that current can be efficiently delivered to the external load “L” and a desired amount of stress in the formed solar cell can be relaxed. In one configuration, it is desirable to make sure that the connection regions 602 are spaced at least a minimum distance “P” apart (FIG. 6B). In one example, the minimum distance “P” is between about 0.1 mm and about 1 mm apart. In another example, the minimum distance “P” is greater than about 0.1 mm apart.

In an alternate embodiment, the connection regions 602 are formed by spot welding, laser welding or e-beam welding of the patterned metal structures 221, 223 and the conductive features 162, 163 together. In this configuration, one may not need to add the solder material 601 between the patterned metal structures 221, 223 and the conductive features 162, 163 to form the connection regions 602. In this configuration, the choice of materials used in the patterned metal structures 221, 223 or the conductive features 162, 163 can be altered as needed to form a reliable electrical connection at the connection regions 602. In one example, an aluminum (Al) or copper (Cu) material is used in the patterned metal structures 221 or 223.

FIG. 7 illustrate another configuration of the external interconnect structure 220 in which the formed connection regions 602 are formed through holes 605 formed in regions of the patterned metal structures 221, 223. In this configuration, as shown in FIG. 7, the connection regions 602 are formed by delivering a conductive material 606 into the holes 605 so that the soldered regions can be formed between the patterned metal structures 221 or 223 and the conductive features 162 or 163. In one embodiment, the conductive material 606 may comprise a conductive adhesive material (e.g., silver particle filled epoxy or silicone based material) or a metal alloy paste such as a solder alloy.

### Bonding Process

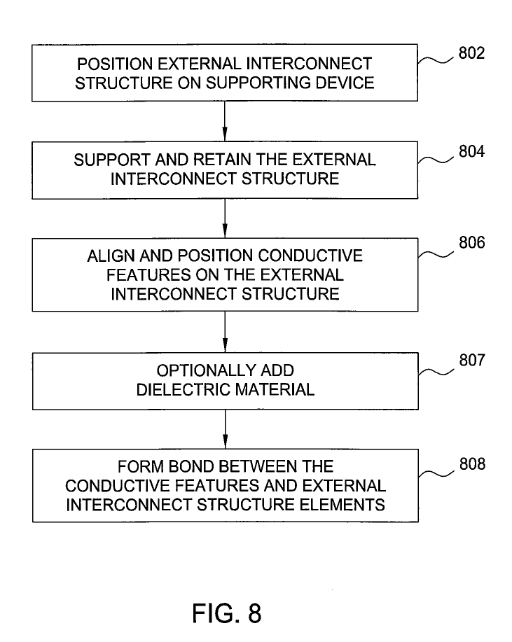

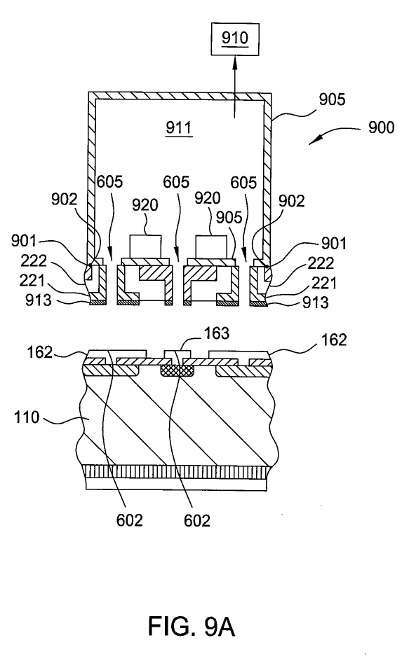

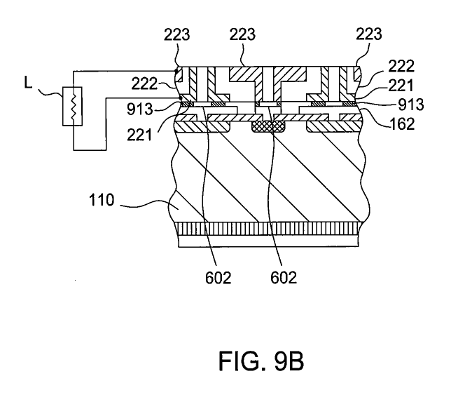

FIGS. 9A-9B are schematic cross-sectional views that illustrate different stages of a solar cell formation process in which an external interconnect structure 220 is bonded to an interconnecting structure (e.g., reference numerals 160, 170) that is formed on a substrate 110. In one example, as shown in FIGS. 9A-9B, the processing sequence is used to bond the external interconnect structure 220 to an interconnecting structure 160. The processing sequence 800 found in FIG. 8 corresponds to the stages depicted in FIGS. 9A-9B, which are discussed herein. FIG. 9B is a side schematic cross-sectional view of a portion of an external interconnect structure 220 that has been bonded to the interconnecting structure 160 using the steps discussed in the processing sequence 800.

FIG. 9A is a side schematic cross-sectional view of a portion of an external interconnect structure 220 that is positioned and aligned over an interconnecting structure, such as an interconnecting structure 160 prior to performing the bonding processing sequence 800. The interconnecting structure 160 can be formed on the substrate 110 using one or more of the deposition and/or patterning process(es) described above.

In one embodiment of the processing sequence 800, prior to bonding the external interconnect structure 220 to the interconnecting structure 160 a conductive material 913, which may be similar to the conductive materials 231, 601 or 606 discussed above, is disposed on the patterned metal structures 221, 223 prior to performing the bonding process. In one configuration the conductive material 913 is disposed in discrete patterned regions, rather than across the surface(s) of the patterned metal structures 221, 223 or the conductive features 162, 163 as shown, by use of a screen printing, inkjet printing, soldering, or other similar process.

At box 802, and as shown in FIG. 8, the external interconnect structure 220 is positioned on a supporting surface 901 of a supporting device 900. In one embodiment, as shown in FIG. 9A, the supporting surface 901 has one or more conventional sealing elements (e.g., o-ring 902) that are adapted to form an enclosed region 911 that is formed by one or more walls 905 of the supporting device 900 and the external interconnect structure 220. In one embodiment, the enclosed region 911 is configured to support a sub-atmospheric pressure, or vacuum, when air is removed from the enclosed region 911 by a pump 910. In one embodiment, the external interconnect structure 220 is positioned on the supporting surface 901 in an automated fashion by use of one or more robotic type devices. In one embodiment, the external interconnect structure 220 is formed in a roll (not shown) that is rolled-out and positioned over the supporting surface 901 by use of conventional roll-to-roll type automation equipment. While FIG. 9A schematically illustrates only a portion of the external interconnect structure 220 that is in contact with the supporting surface 901 this configuration not intended to limiting as to the scope of the invention described herein and is only intended to help illustrate the one embodiment of the bonding processing sequence 800. One skilled in the art will appreciate that the supporting device 900 could be configured to support one or more complete external interconnect structures 220 that are to be bonded to one or more complete substrates 110 at one time without deviating from the scope of the invention described herein.

At box 804, and as shown in FIG. 8, the enclosed region 911 is evacuated to support, hold and retain the external interconnect structure 220 on the supporting surface 901. In one embodiment, as shown in FIG. 9A, evacuation of the enclosed region 911 causes air, which is positioned outside the enclosed region 911, to flow through the holes 605 formed in the external interconnect structure 220 and into the enclosed region 911. The evacuation of the enclosed region 911 will thus allow atmospheric pressure to urge the conductive features 162, 163 against their respective mating patterned metal structures 221, 223 when the two elements are brought together in the next step.

At box 806, the conductive features 162, 163 and patterned metal structures 221, 223 are aligned and positioned to make contact with each other. The alignment and contact between the substrate 110 and external interconnect structure 220 can be performed manually or in an automated fashion using features (e.g., edges) on each of the component to assure that the desired position and alignment is achieved. As noted above, the conductive features 162, 163 and patterned metal structures 221, 223 can be urged, or vacuum “chucked,” together by use of a vacuum created in the enclosed region 911 by the pump 910. The alignment and contact between the substrate 110 and external interconnect structure 220 can be performed by use of a robotic device that is adapted to desirably position the substrate 110 against the external interconnect structure 220.

At box 808, heat is delivered to the conductive features 162, 163 and patterned metal structures 221, 223 to cause a bond and electrical connection to form between these two elements. In one embodiment, heat is applied by a heating element 920 contained in the supporting device 900 to the conductive features 162, 163 and patterned metal structures 221, 223 to cause the conductive material 913 to melt and form a bond there between. In one embodiment, a vacuum is maintained in the enclosed region 911 during at least a part of the processes performed during box 808 to assure that a good contact is formed between the conductive features 162, 163 and the patterned metal structures 221, 223. The heating element 920 can be a conventional resistive heating element, IR lamp(s), or other similar device that can deliver a desired amount of heat to from a bond between the conductive features 162, 163, patterned metal structures 221, 223 and/or conductive material 913. After the bonded components are removed from the supporting surface 901 and allowed to cool a bonded structure can be formed (FIG. 9B).

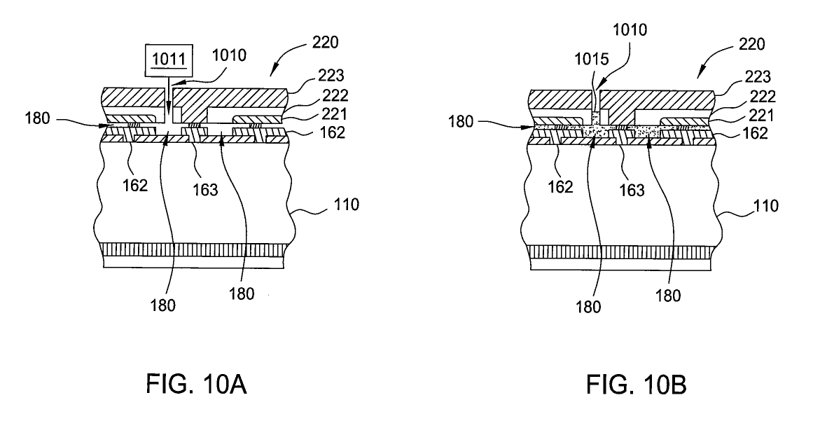

FIGS. 10A-10B are close-up schematic cross-sectional views that illustrate different stages of processes performed at box 807 in which a dielectric material is added between the external interconnect structure 220 and substrate 110. The dielectric material is generally used to provide electrical isolation and/or a barrier from environmental attack when the completed solar cell device is placed in normal use. In one embodiment, a dielectric material 1015 is added between the external interconnect structure 220 and substrate 110 before the process(es) performed at box 808 are performed to allow the heat added during the processes performed at box 808 to densify or cure the disposed dielectric material 1015. During the steps performed in box 807, after the external interconnect structure 220 and substrate 110 have been brought into contact (box 806), a dielectric material delivery source 1011 is positioned to deliver a dielectric material to the air gaps 180 formed between the external interconnect structure 220 and substrate 110. In one example, the dielectric material delivery source 1011 is positioned to deliver the dielectric material to a plurality of holes 1010 formed in the external interconnect structure 220 which are positioned in fluid communication with the air gaps 180 (FIGS. 3B, 5C and 6B) found between the external interconnect structure 220 to an interconnecting structure 160. Next, as shown in FIG. 10B, the dielectric material 1015 is disposed between the external interconnect structure 220 and interconnecting structure 160 to substantially fill up the air gaps 180 and isolate the respective conductive features 162, 163 and patterned metal structures 221, 223 from each other. In one embodiment, the dielectric material 1015 is polymeric material, such as silicone, epoxy, or other similar material.

### Alternate Interconnect Structure(s)

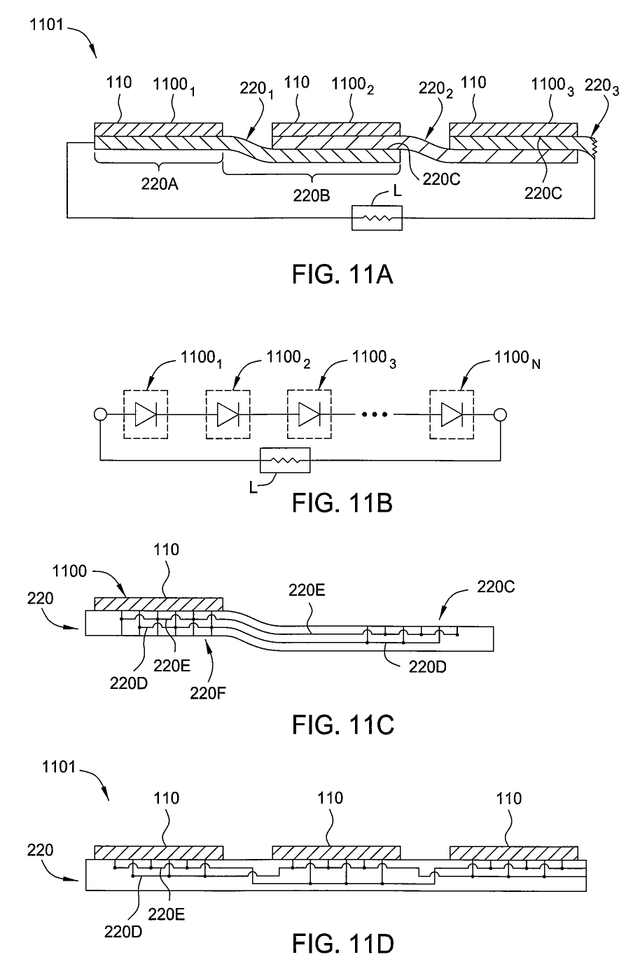

FIG. 11A-11C illustrate various embodiments of interconnected solar cell array 1101 of solar cells 1100 that that are bonded together to form an interconnected solar cell array. As shown, the solar cell assemblies 1100 comprise a substrate 110 and external interconnect structure 220 that are used to easily and cost effectively interconnect multiple solar cell assemblies 1100 together to form a solar cell array 1101 that can be used to generate electricity. The configurations discussed herein can be used to inexpensively fabricate completed modules by reducing the time required to fabricate and interconnect individual solar cells. In one embodiment, the solar cell assemblies 1100 are similar to the structures discussed above in conjunction with reference numerals 200, 500, and 600. FIG. 11A is a side view of a solar cell array 1101 of solar cell assemblies 1100 that are connected in a desired pattern to generate a desired current and voltage when exposed to sun light. FIG. 11B illustrates an electrical schematic of an embodiment of an electrically interconnected solar cell array 1101 of solar cell assemblies (e.g., reference numerals 1100₁, 1100₂, 1100₃ . . . 1100_{N}). In one example, an array of N solar cell assemblies 1100 are connected in series to form a solar cell array 1101 that is connected to an external load “L”, where N is any number of solar cells greater then two.

Referring to FIG. 11A, in one embodiment, the external interconnect structure 220 found in a solar cell assembly 1100 contains a substrate connection region 220A and external connection region 220B which is used to connect a solar cell assembly 1100 to other solar cell assemblies 1100 or other external wiring (not shown) that can be used to connect the interconnected solar cell array 1101 to the external load “L”. The substrate connection region 220A is generally the region(s) of the external interconnect structure 220 that has the patterned metal structures 221, 223 which are in communication the conductive features, such as the conductive features 162, 163, discussed above. The external connection region 220B portion of the external interconnect structure 220 generally comprises a region that has wiring elements that are used to separately connect each of the patterned metal structures 221, 223 to conductive features in adjacent solar cell assemblies 1100. In one embodiment, as shown in FIG. 11C, the external connection structure 220 comprises a first metal layer 220D (e.g., patterned metal structure 221 in FIG. 2) that is in electrical communication with conductive features 162 and second metal layer 220E (e.g., patterned metal structure 223 in FIG. 2) that is in electrical communication with the conductive features 163. The first metal layer 220D and second metal layer 220E are each configured to mate with the interconnecting features of another solar cell assembly 1100 at a connection interfaces 220C and 220F. In one example, of solar array having two solar cells connected in series (e.g., N=2 in FIG. 11B) the first metal layer 220D in a first interconnecting structure 220₁ of a first solar cell assembly 1100₁ is placed in electrical communication with the second metal layer 220E in a second interconnecting structure 220₂ of a second solar cell 1100₂ and the external load “L” is connected between the second metal layer 220E in a first interconnecting structure 220₁ and the first metal layer 220D in a second interconnecting structure 220₂. One skilled in the art would appreciate that a different scheme could be used to connect the solar cells in parallel, however, in this case the first metal layers 220D and second metal layers 220E in each of the solar cells, for example, the first and second solar cell assemblies 1100₁, 1100₂ would each be connected together.

FIG. 11D is a side view of one embodiment of the solar cell array 1101 in which multiple substrates 110 are connected to an external interconnect structure 220 that has been formed for easy interconnection. In one embodiment, the external interconnect structure 220 contains the required electrical connections need to interconnect each of the substrates 110 in series and/or parallel as desired. In one example, as shown in FIG. 11D, the configuration of the interconnecting metal layers in the external interconnect structure 220 is configured to connect to the desired conductive features formed on each of the substrates 110 in the solar cell array 1101.

FIG. 12A is a plan view of a wire mesh type patterned metal structure 221 that can be integrally formed in an external interconnect structure 220 and used to carry current from a formed solar cell device. In general, one or more of the patterned metal structures 221, 223 in an external interconnect structure 220 can be formed from an electrically conductive wire mesh type material that is used to interconnect portions of a formed solar cell device. In one example, as shown in FIG. 12A, a patterned metal structure 221 comprises one or more conductive elements 1221, such a metal containing wire material that is woven or connected to form a wire mesh that is bonded to the surface of a conductive feature 162 in a interconnecting structure 160. In general, the use of an external interconnect structure 220 containing a wire mesh can help improve material utilization, material cost, and reduce the intrinsic or extrinsic stress created in the thin solar cell substrates by reducing the stiffness of the patterned metal structures in the external interconnect structure 220 and allowing the required thickness of the deposited conducting feature(s) on the surface of the substrate to be minimized.

In one embodiment, the conductive elements 1221 in at least one of the patterned metal structures 221, 223 is bonded to the desired conducting feature (e.g., reference numerals 162, 163) using a solder material that is disposed between the conductive elements 1221 and the conducting feature. In another embodiment, portions of the conductive elements 1221 are welded to the desired conductive feature to form a good electrical connection there-between. In one example, the conductive elements 1221 are tack welded to the conductive layer at multiple points 1222 (FIG. 12A). It is generally desirable to form the conductive elements 1221 and the conducting feature(s) 162 from materials that are compatible and/or weldable. In one example, the conductive elements 1221 and the conducting feature 162 are both formed from, or coated with, an aluminum, copper, silver, nickel, tin, lead, or zinc material (or alloys thereof) that can be readily laser beam welded together at various points 1222 across the surface of a solar cell device.

FIG. 12B illustrates a side cross-sectional view of solar cell 200 that contains patterned metal structures 221, 223 that are each formed from conductive elements 1221, which are separately connected to the conductive features 162, 163. One skilled in the art will appreciate that in the case where both of the patterned metal structures 221 and 223 are formed from a wire mesh material that layers of wire mesh can be separately configured and aligned to interconnect with each of the desired conductive features so that they are electrically isolated from one another by use of an insulating material layer (e.g., polymeric material). In one example, the insulating material layer is part of the substrate 222, or is a separate material that is disposed over a portion of each of the conductive elements 1221. While FIGS. 12A-12B illustrate an all back contact type solar cell device similar to the configuration shown in FIG. 2 to illustrate various different embodiments of the invention, this configuration is not intended to limiting as to the scope of the invention described herein.

### Second Alternate Interconnect Structure and Formation Process

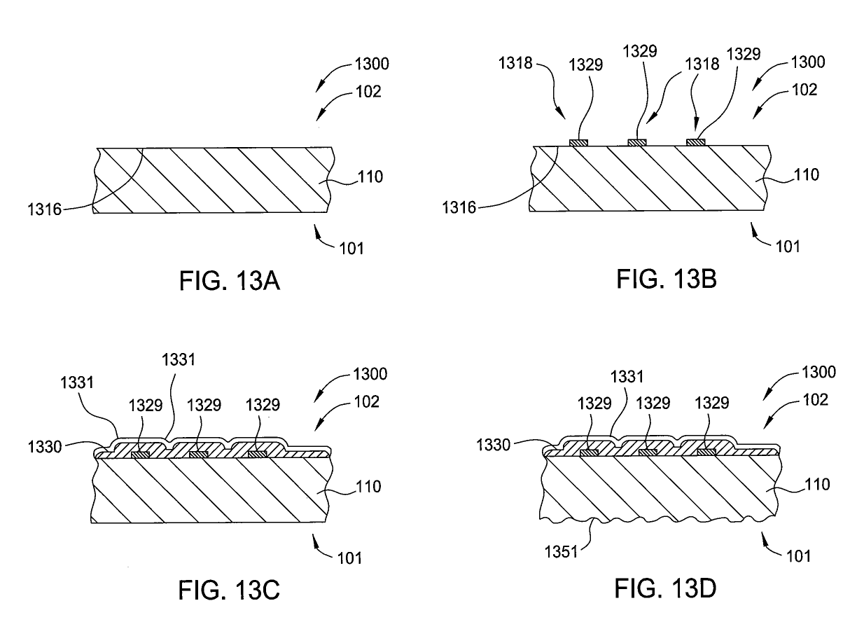

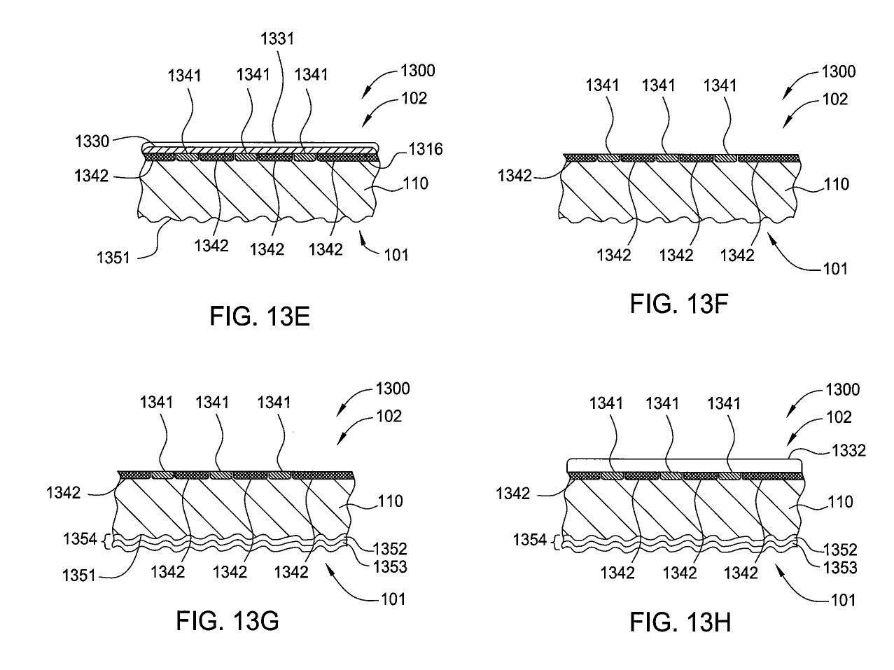

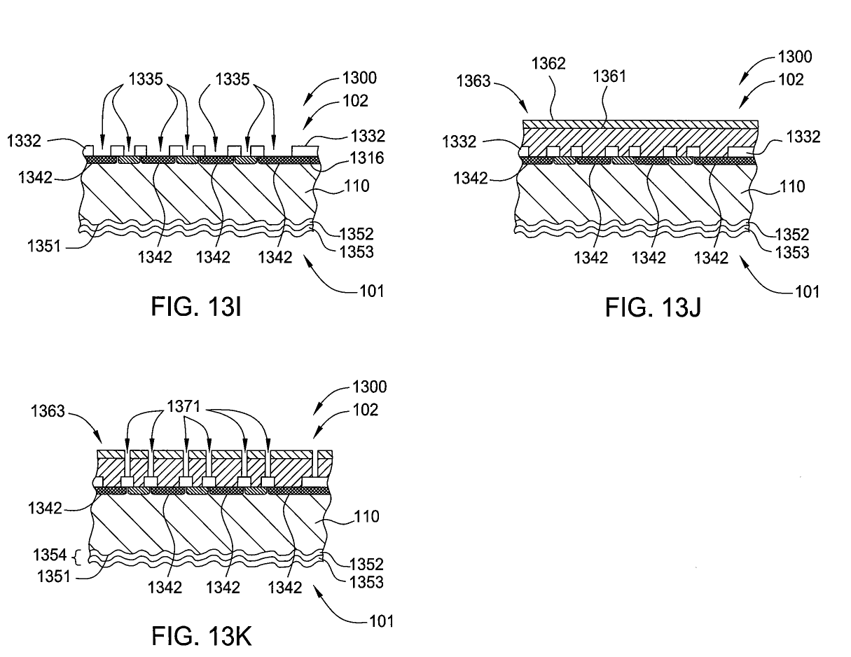

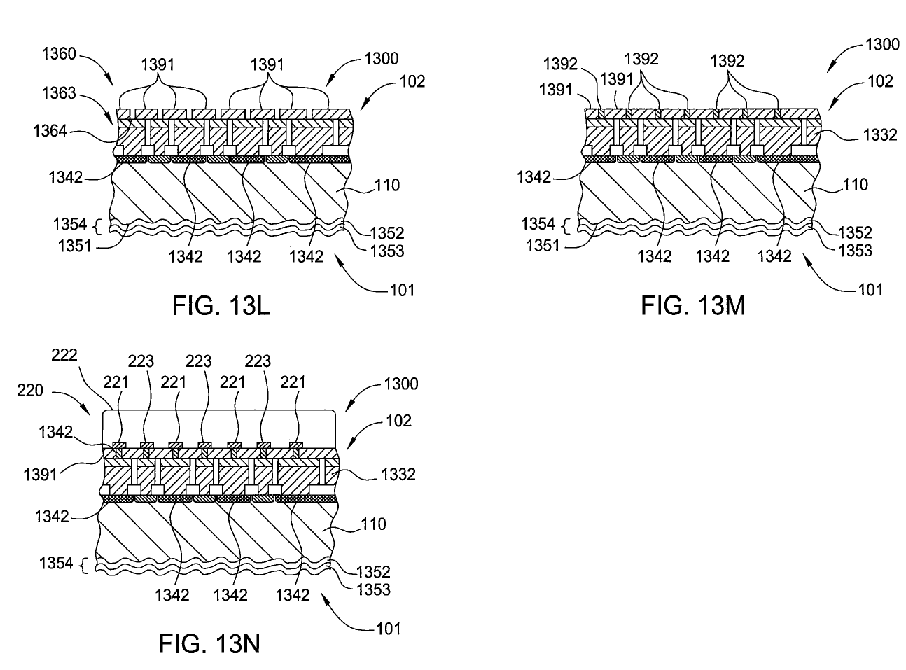

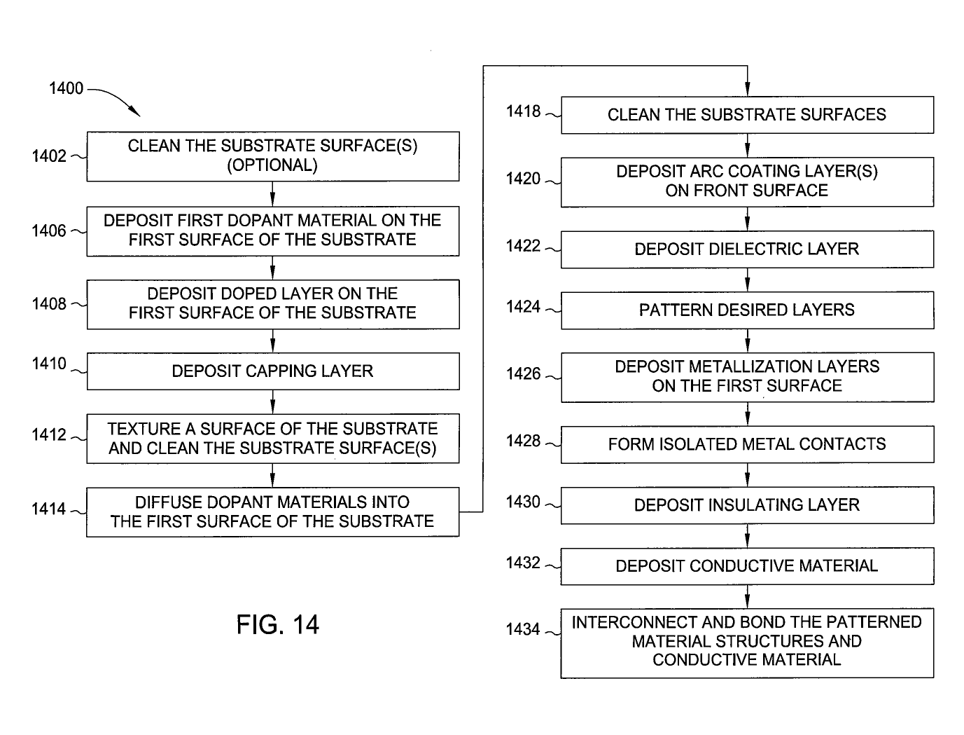

FIGS. 13A-13N illustrate schematic cross-sectional views of a solar cell substrate 110 during different stages of a processing sequence used to form a solar cell 1300 device that has a contact structure formed on a surface 102. FIG. 14 illustrates a process sequence 1400 used to form the active region(s) and/or contact structure on the solar cell 1300. The sequence found in FIG. 14 corresponds to the stages depicted in FIGS. 13A-13N, which are discussed herein.

At box 1402, and as shown in FIG. 13A, the surfaces of the substrate 110 are cleaned to remove any undesirable material or roughness. In one embodiment, the clean process may be performed using a batch cleaning process in which the substrates are exposed to a cleaning solution. The substrates can be cleaned using a wet cleaning process in which they are sprayed, flooded, or immersed in a cleaning solution. The clean solution may be a conventional SC1 cleaning solution, SC2 cleaning solution, HF-last type cleaning solution, ozonated water cleaning solution, hydrofluoric acid (HF) and hydrogen peroxide (H₂O₂) solution, or other suitable and cost effective cleaning solution. The cleaning process may be performed on the substrate between about 5 seconds and about 600 seconds, such as about 30 seconds to about 240 second, for example about 120 seconds. Another embodiment, the wet cleaning process may include a two step process in which a saw damage removal step is first performed on the substrate and then a second preclean step is performed. In one embodiment, the saw damage removal step includes exposing the substrate to an aqueous solution comprising potassium hydroxide (KOH) that is maintained at about 70° C. for a desired period of time. The preclean solution and processing step may be similar to the clean process described above.

At box 1406, as shown in FIGS. 13B and 14, a first dopant material 1329 is deposited onto a plurality of the isolated regions 1318 formed on the surface 1316 of the substrate 110. In one embodiment, the first dopant material 1329 is deposited or printed in a desired pattern by the use of screen printing, ink jet printing, rubber stamping or other similar process. In one embodiment, the first dopant material 1329 is deposited using a screen printing process performed by a Softline™ tool available from Baccini S.p.A a division of Applied Materials Inc. of Santa Clara, Calif. The first dopant material 1329 may initially be a liquid, paste, or gel that will be used to form a doped region in a subsequent processing step. In some cases, after disposing the first dopant material 1329 to form the isolated regions 1318, the substrate is heated to a desirable temperature to assure that the first dopant material 1329 will remain on the surface 1316, and cause the dopant material 1329 to cure, densify, and/or form a bond with the surface 1316. In one embodiment, the first dopant material 1329 is a gel or paste that contains an n-type dopant this disposed over a n-type doped substrate 110. Typical n-type dopants used in silicon solar cell manufacturing are elements, such as, phosphorus (P), arsenic (As), or antimony (Sb). In one embodiment, the first dopant material 1329 is phosphorous containing dopant paste that is deposited on the surface 1316 of the substrate 110 and the substrate is heated to a temperature of between about 80 and about 500° C. In one embodiment, the first dopant material 1329 may contain materials selected from a group consisting of phosphosilicate glass precursors, phosphoric acid (H₃PO₄), phosphorus acid (H₃PO₃), hypophosphorous acid (H₃PO₂), and/or various ammonium salts thereof. In one embodiment, the first dopant material 1329 is a gel or paste that contains about a phosphosilicate material with an atomic ration of Phosphorous to Silicon atoms of between 0.02 and about 0.20.

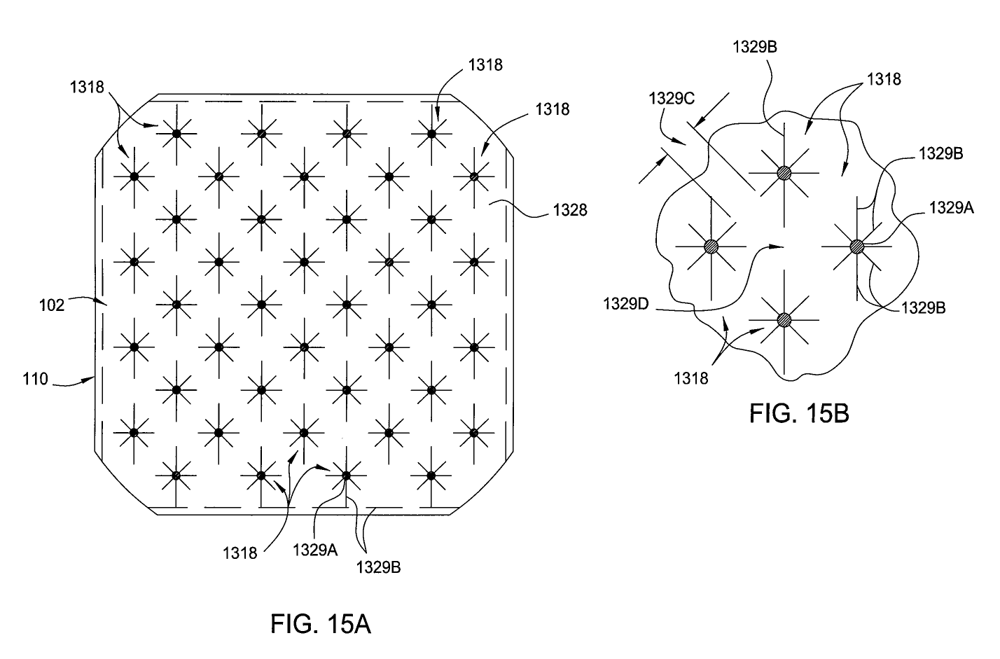

FIG. 15A illustrates a plan view of the surface 102 of the substrate 110 on which the isolated regions 1318 containing the first dopant material 1329 has been formed in a desirable shape and pattern. In one embodiment, as shown in FIG. 15A, the isolated regions 1318 are disposed in a rectangular array across the surface 102 of the substrate 110. In another embodiment, the isolated regions 1318 may be disposed in a hexagonal close packed pattern across the surface 102 of the substrate 110. In either configuration it is desirable to assure that the nearest neighbor distance and/or spacing is uniform between the formed isolated regions 1318. In one configuration, the isolated regions 1318 are formed in a desirable shape to help assure that a desired density and spacing is achieved between each of the isolated regions 1318 to uniformly collect the generated carriers formed within the substrate 110. The alignment, spacing and shape of the isolated regions 1318 across the surface 102 of the substrate 110 is generally important to assure that the distance that the minority carriers need to travel before they are collected, by their respective sides of the formed junction (e.g., p-n junction, solar cell junction), is short enough and generally uniform in density so that the solar cell efficiency is maximized. In one example, as shown in FIGS. 15A and 15B, the isolated regions 1318 are formed in a “star” shaped pattern having a central doped region 1329A and plurality of doped finger regions 1329B that are disposed across the surface 102 in a desired pattern. In one embodiment, the central doped region 1329A is circular region that is less than about 2 mm in diameter. In another embodiment, the central doped region 1329A is circular region that is between about 0.5 and about 2 mm in diameter. In one embodiment, the isolated regions 1318 have a plurality of doped finger regions 1329B that are connected to the central doped region 1329A, and are between about 600 and about 1000 μm and have a desirable length, such as between 0.1 mm and about 10 mm long. In one example, the doped finger regions 1329B are about 800 μm wide. In one example, the maximum distance 1329C, 1329D between the doped finger regions 1329B in adjacently positioned isolated regions 1318 is between about 1 mm and about 4 mm, preferably about 3 mm.

At box 1408, and as shown in FIG. 13C, a doped layer 1330 is deposited over the surface 102 of the solar cell 1300. The doped layer 1330 is advantageously used as an etch mask that minimizes and/or prevents the surface 102 from being etched during the subsequent surface texturing process performed at box 1412, which is used to roughen the opposing surface 101. In general, the etch selectivity of the doped layer 1330 to the exposed material on the opposing surface 101 should be relatively high to prevent material loss from the various regions formed on the surface 102 during the texturizing process. In one example, the etch selectivity of the material on the opposing surface 101 to the doped layer 1330 is at least about 100:1. In one embodiment, the deposited doped layer 1330 is an amorphous silicon containing layer that is about 50 and about 500 Å thick and contains a p-type dopant, such as boron (B). In one embodiment, the doped layer 1330 is a PECVD deposited BSG layer that is formed over the surface 102 of the solar cell 1300.

In one embodiment of the processes performed at box 1408, the surface 102 of the solar cell 1300 is treated with a plasma containing a gas containing at least one or more of hydrogen (H₂), oxygen (O₂), ozone (O₃) or nitrous oxide (N₂O) prior to deposition of a doped layer 1330 comprising boron. The plasma treatment can help to improve adhesion of the doped layer 1330 to the surface 102. If the dopant material 1329 contains any residual carbon, an RF plasma treatment can be used to reduce the carbon concentration at the surface and the bulk of the material on surface 102, prior to deposition of a boron doped layer 1330.

In one embodiment of the process performed at box 1408, the deposited doped layer 1330 is a doped amorphous silicon (a-Si) layer that is formed over the surface 102 of the solar cell 1300. In one embodiment, the doped amorphous silicon layer is an amorphous silicon hydride (a-Si:H) layer that is formed at a temperature of about 200° C. to minimize the amount of vaporization of the dopant material, such as phosphorous (P) from the previously deposited first dopant material 1329. In one example, the doped layer 1330 is deposited using a gas mixture containing trimethylborane B(CH₃)₃, silane (SiH₄) and hydrogen (H₂). In one embodiment, the deposited doped layer 1330 is a doped amorphous silicon (a-Si) layer that is less than about 500 Å thick and contains a p-type dopant, such as boron (B). In one example, the doped amorphous silicon (a-Si) layer is formed in a PECVD chamber that uses about a 20% trimethyl-borane (TMB) to silane (SiH₄) molar ratio, which in this example is equal to atomic ratio, during processing to form about a 200 Å thick film. In another example, the doped amorphous silicon (a-Si) layer is formed in a PECVD chamber that uses about a 10% diborane (B₂H₆) to silane (SiH₄) molar ratio, which in this example is equal to an atomic ratio of 0.20, to form a 200 Å thick film It is believed that using a doped amorphous silicon film has advantages over other conventional doped silicon oxides, since the activation energy required for diffusion of the dopant atoms from a deposited amorphous silicon film is much lower than from a doped oxide layer.

In another embodiment of the process performed at box 1408, the deposited doped layer 1330 is a doped amorphous silicon carbide (a-SiC) layer that is formed over the surface 1316 of the solar cell 1300. In one embodiment, an amorphous SiC layer is formed using a PECVD process at a temperature of about <400° C. to minimize the amount of vaporization of the dopant material, such as phosphorous (P) from the previously deposited first dopant material 1329. In one embodiment, a Boron doped amorphous SiC layer is formed using a PECVD process at a temperature of less than about 200° C. In one example, the doped layer 1330 is deposited using a gas mixture containing trimethyl-borane (TMB or B(CH₃)₃), silane (SiH₄) and hydrogen (H₂).

At box 1410, as illustrated in FIG. 13C, a capping layer 1331 is deposited over the surface of the doped layer 1330. The capping layer 1331 is advantageously used to minimize the migration of the dopant atoms contained within the doped layer 1330 or the first dopant material 1329 to undesirable regions of the substrate, such as the front surface 101, during the subsequent solar cell formation processing steps. In one embodiment, the capping layer 1331 is a dielectric layer that is formed at a sufficient density and thickness to minimize or prevent the migration of dopant atoms within the layers disposed below the capping layer 1331 from moving to other regions of the solar cell. In one example, the capping layer 1331 comprises a silicon oxide, a silicon nitride or a silicon oxynitride containing material. In one embodiment, the capping layer 1331 is a silicon dioxide layer that is greater than about 1000 Å thick. In one embodiment, the capping layer 1331 is a silicon dioxide layer that is deposited using a PECVD deposition process. The capping layer 1331 can also be formed from a material that minimizes and/or prevents the surface 102 from being etched during the subsequent texturizing process performed at box 1412.

At box 1412, as shown in FIGS. 13D and 14, a texturizing process is performed on the opposing surface 101 of the substrate 110 to form a textured surface 1351. In one embodiment, the opposing surface 101 of the substrate 110 is the front side 101 of a solar cell substrate that is adapted to receive sunlight after the solar cell has been formed. An alkaline silicon wet etching chemistry is generally preferred when texturizing a surface having a p-type doped layer 1330, due to the high etch selectivity between the doped layer 1330 and/or capping layer 1331 and the exposed material found on the opposing surface 101. An example of an exemplary texturization process is further described in the U.S. Provisional Patent Application Ser. No. 61/148,322, filed Jan. 29, 2009 (Attorney Docket No. APPM/13323L02), which is herein incorporated by reference in its entirety.

At box 1414, as shown in FIGS. 13E and 14, the substrate is heated to a temperature greater than about 800° C. to causes the doping elements in the first dopant material 1329 and the doping elements contained in the doped layer 1330 to diffuse into the surface 1316 of the substrate 110 to form a first doped region 1341 and a second doped region 1342, respectively, within the substrate 110. Thus, the formed first doped region 1341 and second doped region 1342 can thus be used to form regions of a point contact type solar cell. In one example, the first dopant material 1329 contains an n-type dopant and the doped layer 1330 contains a p-type dopant that forms an n-type region and a p-type region, respectively, within the substrate 110. In one embodiment, the substrate is heated to a temperature between about 800° C. and about 1300° C. in the presence of nitrogen (N₂), oxygen (O₂), hydrogen (H₂), air, or combinations thereof for between about 1 and about 120 minutes. In one example, the substrate is heated in a rapid thermal annealing (RTA) chamber in a nitrogen (N₂) rich environment to a temperature of about 1000° C. for about 5 minutes. Referring to FIG. 15A, after performing the processes in box 1414 the formed doped regions will generally have a shape and pattern matching the shape and pattern of the isolated regions 1318 disposed on the surface 102 during the processes performed at box 1406. In one example, as shown in FIG. 15A, the surface 102 contains 40 n-type regions that are each formed in a “star” shape, which match the pattern of the first dopant material 1329. In one embodiment, the pattern of the first doped region 1341 formed by the first dopant material 1329 are also surrounded by the second doped region 1342 (e.g., p-type region) that is illustrated and labeled as a field region 1328 in FIG. 15A.

Next, at box 1418, as shown in FIGS. 13F and 14, a cleaning process is performed on the substrate 110 after the texturizing process has been completed to remove the layers, such as the doped layer 1230 and the capping layer 1231, from the surface 102 of the substrate. In one embodiment, the clean process may be performed by wetting the substrate with a cleaning solution to clean the surface of the substrate before the subsequent deposition sequence is performed on the various regions of the substrate. Wetting may be accomplished by spraying, flooding, immersing or other suitable technique. The cleaning solution may be an SC1 cleaning solution, an SC2 cleaning solution, HF-last type cleaning solution, ozonated water solution, hydrofluoric acid (HF) and hydrogen peroxide (H₂O₂) solution, or other suitable and cost effective cleaning process or combinations thereof. The clean process may be performed on the substrate between about 5 seconds and about 600 seconds, such as about 30 seconds to about 240 second, for example about 120 seconds.

At box 1420, as shown in FIGS. 13G and 14, an antireflection layer 1354 is formed on the surface 1351 of the opposing surface 101. In one embodiment, the antireflection layer 1354 comprises a thin passivation/antireflection layer 1353 (e.g., silicon oxide, silicon nitride layer). In another embodiment, the antireflection layer 1354 comprises a thin passivation/antireflection layer 1353 (e.g., silicon oxide, silicon nitride layer) and a transparent conductive oxide (TCO) layer 1352. In one embodiment, the passivation/antireflection layer 1353 may comprise an intrinsic amorphous silicon (i-a-Si:H) layer and/or n-type amorphous silicon (n-type a-Si:H) layer stack followed by a transparent conductive oxide (TCO) layer and/or an ARC layer (e.g., silicon nitride), which can be deposited by use of a physical vapor deposition process (PVD) or chemical vapor deposition process. The formed stack is generally configured to generate a front surface field effect to reduce surface recombination and promote lateral transport or electron carriers to nearby n+ doped contacts on the backside of the substrate.

While FIG. 13G illustrates an antireflection layer 154 that contains a thin passivation/antireflection layer 1353 and a TCO layer 1352 this configuration is not intended to be limiting as to the scope of the invention described herein, and is only intended to illustrate one example of an antireflection layer 1354. One will note that the preparation of the opposing surface 101 completed at boxes 1412 and 1420 may also be performed prior to performing the process(es) at box 1404, or other steps in the process sequence 1400, without deviating from the basic scope of the invention described herein.

At box 1422, as shown in FIG. 13H, a dielectric layer 1332 is formed over surface 102 so that electrically isolated regions can be provided between the various formed n-type and p-type regions in the formed solar cell 1300. In one embodiment, the dielectric layer 1332 is a silicon oxide layer, that may be formed using a conventional thermal oxidation process, such a furnace annealing process, a rapid thermal oxidation process, an atmospheric pressure or low pressure CVD process, a plasma enhanced CVD process, a PVD process, or applied using a sprayed-on, spin-on, roll-on, screen printed, or other similar type of deposition process. In one embodiment, the dielectric layer 1332 is a silicon dioxide layer that is between about 50 Å and about 3000 Å thick. In another embodiment the dielectric layer is a silicon dioxide layer that is less than about 2000 Å thick. In one embodiment, the surface 102 is the backside of a formed solar cell device. It should be noted that the discussion of the formation of a silicon oxide type dielectric layer is not intended to be limiting as to the scope of the invention described herein since the dielectric layer 1332 could also be formed using other conventional deposition processes (e.g., PECVD deposition) and/or be made of other dielectric materials.

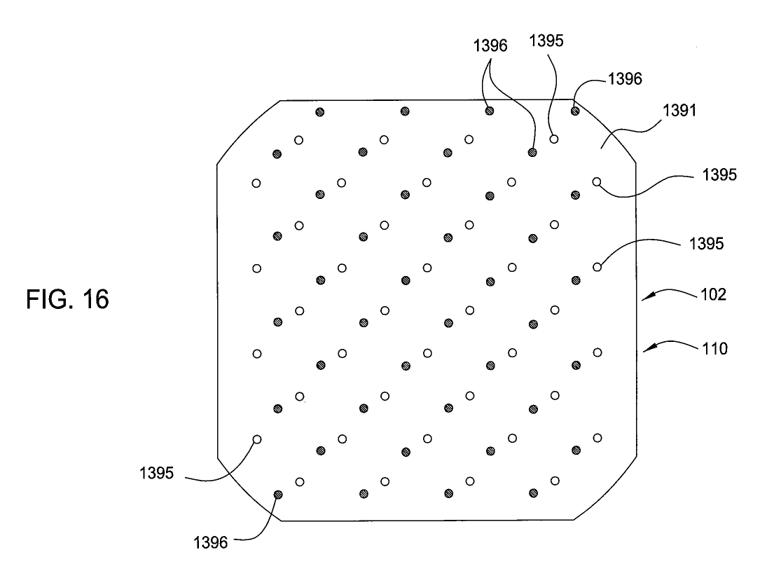

In box 1424, as shown in FIGS. 131 and 14, regions of the dielectric layer 1332, and any remaining the capping layer 1331 and/or the doped layer 1330 are etched by conventional means to form a desired pattern of exposed regions 1335 that can be used to form the interconnecting structure 1360 on the substrate surface. In general, the pattern formed in the dielectric layer 1332 aligned with the underlying n+ and p+ doped regions so that desired electrical connections can be formed within the solar cell 1300. In one example, the etched pattern is similar to the pattern illustrated in FIG. 16, which match and is align with portions of the underlying n+ and p+ doped regions formed in previous steps. Typical etching processes that may be used to form the patterned exposed regions 1335 on the backside surface 102 may include but are not limited to patterning and dry etching techniques, laser ablation techniques, patterning and wet etching techniques, or other similar processes that may be used to form a desired pattern in the dielectric layer 1332, capping layer 1331 and doped layer 1330. The exposed regions 1335 generally provide surfaces through which electrical connections can be made to the backside surface 102 of the substrate 110. An example of an etching gel type dry etching process that can be used to form one or more patterned layers is further discussed in the commonly assigned and copending U.S. patent application Ser. Nos. 12/274,023 [Atty. Docket #: APPM 12974.02], filed Nov. 19, 2008, which is herein incorporated by reference in its entirety.

At box 1426, as illustrated in FIGS. 13J and 14, a conducting layer 1363 is deposited over the surface 102 of the substrate 110. In one embodiment, the formed conducting layer 1363 is between about 500 and about 50,000 angstroms (Å) thick and contains a metal, such as aluminum (Al), silver (Ag), tin (Sn), cobalt (Co), rhenium (Rh), nickel (Ni), zinc (Zn), lead (Pb), palladium (Pd), molybdenum (Mo) titanium (Ti), tantalum (Ta), vanadium (V), tungsten (W), or chrome (Cr). However, in some cases copper (Cu) may be used as a second layer, or subsequent layer, that is formed on a suitable barrier layer (e.g., TiW, Ta, etc.). In one embodiment, the conducting layer 1363 contains two layers that are formed by first depositing an aluminum (Al) layer 1361 by a physical vapor deposition (PVD) process, or evaporation process, and then depositing a silver (Ag) or tin (Sn) capping layer 1362 by use of a PVD deposition process.

At box 1428, as illustrated in FIGS. 13K and 14, the conducting layer 1363 is patterned to electrically isolate desired regions of the substrate 110 to form a patterned interconnecting structure 1360. In one embodiment, the conducting layer 1363 is patterned using a screen printed etching paste that is patterned on the top surface of the conducting layer 1363 to etch through the formed one or more layers of the conducting layer 1363 by heating the substrate to a desired temperature. Etch pastes that may be used to etch through the conductive layer may be purchased from Merck KGaA. In another embodiment, the regions of the substrate 110 are electrically isolated by forming channels 1371 in the conducting layer 1363 by one or more laser ablation, patterning and wet or dry etching, or other similar techniques. In general, it is desirable to form or align the channels 1371 so that a separate or interdigitated electrical connection structure is formed between the p-type and n-type regions of the solar cell device.

At box 1430, as shown in FIGS. 13L and 14, an insulating material 1391 is deposited onto the surface 1364 of the patterned interconnecting structure 1360. FIG. 16 is a plan view of the surface 102 on which the insulating material 1391 is disposed. It should be noted that the underlying structure below the deposited insulating material 1391 is not shown in FIG. 16 for clarity. In one embodiment, the insulating material 1391 is disposed in a pattern on the surface 102 of the substrate 110 having a plurality of holes 1395, 1396 that are each formed in the insulating material 1391 during the deposition process. In one embodiment, the holes 1395, 1396 are between about 0.1 mm and about 1.5 mm in diameter. In one embodiment, the holes 1395, 1396 are aligned and adapted to contact the doped pattern formed by the isolated regions 1318 (e.g., n-type region) and field region 1328 (e.g., p-type region), respectively. In another embodiment, the holes 1395, 1396 are nominally smaller than the center doped regions 1329A formed in step 1406 (FIGS. 15A-15B). In one configuration, the holes 1395, 1396 are aligned with desired regions of the conducting layer 1363 in the patterned interconnecting structure 1360 (box 1428) so that desirable electrical connections can be formed between the external interconnect structure 220 and the patterned interconnecting structure 1360 in a subsequent step. In one embodiment, the insulating material 1391 is deposited or printed in a desired pattern by the use of ink jet printing, rubber stamping, screen printing, or other similar process. In one embodiment, the insulating material 1391 is deposited using a screen printing process performed in a Softline™ tool available from Baccini S.p.A a division of Applied Materials Inc. of Santa Clara, Calif. The insulating material 1391 may be a polymeric material that comes in a liquid, paste, or gel form that is used to form a patterned compliant and insulating region(s) on portions of the surface 1364 of the patterned interconnecting structure 1360. In one embodiment, the insulating material 1391 is an epoxy, silicone or other similar material. In one embodiment, the insulating material 1391 is a UV curable silicone material. In some cases, after disposing the insulating material 1391 on the surface 1364 the insulating material 1391 may exposed to heat, light (e.g., UV light) or other form of energy to assure that the insulating material 1391 will cure, densify, and/or form a bond with the surface 1364.

At box 1432, as shown in FIGS. 13M and 14, a conductive material 1392 is deposited into the holes 1395, 1396 formed in the insulating material 1391 so that conductive paths can be formed between the patterned interconnecting structure 1360 and the patterned metal structures 221, 223 in the external interconnect structure 220 in a subsequent step (FIG. 13N). In one embodiment, the conductive material 1392 is deposited into the holes 1395, 1396 by use of an ink jet printing, rubber stamping, screen printing, or other similar process. In one embodiment, the conductive material 1392 is deposited using a screen printing process performed by a Softline™ tool available from Baccini S.p.A a division of Applied Materials Inc. of Santa Clara, Calif. The conductive material 1392 may be a polymeric material that comes in a liquid, paste, or gel that is used to form a patterned compliant and conductive path between regions of the conductive layer 1363 and the patterned metal structures 221, 223. In one embodiment, the conductive material 1392 is a metal filled epoxy, silicone or other similar material that has a conductivity that is high enough to conduct the electricity generated by the formed solar cell 1300. In one example, the conductive material 1392 has a resistivity that is about 7×10⁻⁵ Ohm-centimeters or less. To minimize the resistance of the conductive paths formed by the conductive material 1392 the thickness of the insulating material 1391 and conductive material 1392 is less than about 50 μm. In one example, the thickness of the insulating material 1391 and conductive material 1392 is between about 15 and about 30 μm. In one embodiment, the conductive material 1392 is a heat curable silver (Ag) impregnated silicone material or epoxy material. In some cases, after disposing the conductive material 1392 in the holes 1395, 1396 of the insulating material 1391 the substrate 110 may exposed to heat, light (e.g., UV light) or other form of energy to assure that the conductive material 1392 will cure, densify, and/or form a bond with the material found on surface 1364 of the patterned interconnecting structure 1360.

At box 1434, heat and pressure is delivered to the conductive material 1392, insulating material 1391 and patterned metal structures 221, 223 in the external interconnect structure 220 to form electrical connections between the metal structures 221, 223 and the exposed portions of the conductive material 1392 disposed in the holes 1395, 1396. During this process a bond is also advantageously formed between the external interconnect structure 220, the insulating material 1391 and surface 1364 of the substrate 110 to cover and isolate the surface 102 from the corrosive elements in the external environment when the solar cell is placed in service. In one embodiment, heat is applied by a heating element (not shown) which causes the conductive material 1392 to form a bond between its respective metal structure 221, 223. The heating element can be a conventional resistive heating element, IR lamp(s), or other similar device that can deliver a desired amount of heat to from a bond between the metal structures 221, 223 in the external interconnect structure 220, the insulating material 1391, conductive material 1392 and substrate 110.

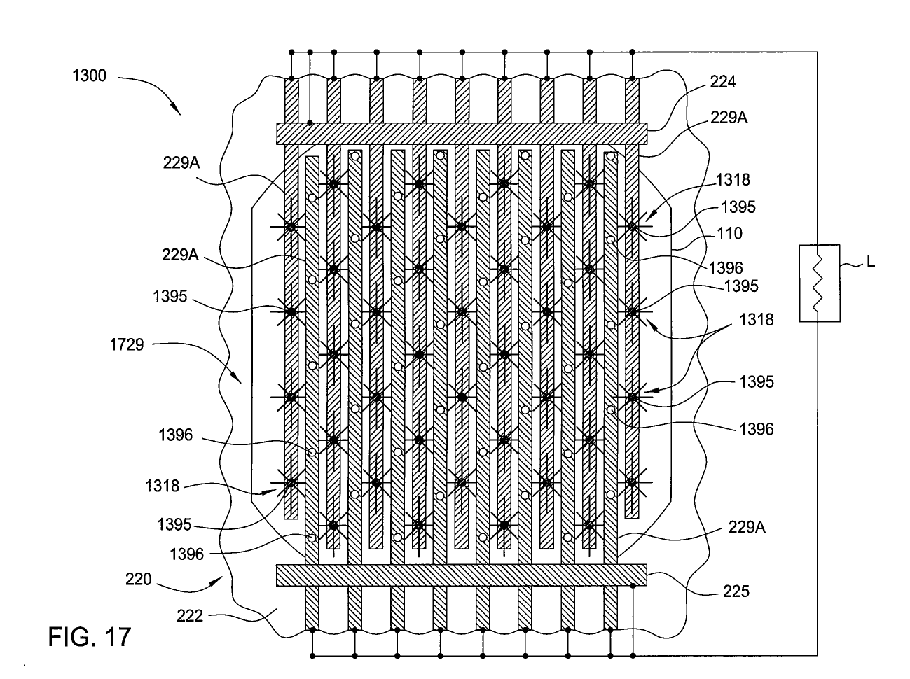

FIG. 17 is a schematic plan view of one embodiment of an interdigitated interconnect structure 1729 formed in an external interconnect structure 220 that is aligned and bonded to the conductive material 1392 and insulating material 1391 formed on the substrate 110. In this configuration, the interdigitated interconnect structure 1729 has separate patterned metal structures 221, 223 that have interdigitated fingers 229A which are each separately connected to the holes 1395 that are coupled to one region of the solar cell device (e.g., n-type regions) and the holes 1396 that are coupled to another region of the solar cell device (e.g., p-type regions). In one embodiment, as shown in FIG. 17, each of the interdigitated fingers 229A are either connected to a first busline 224 or a second busline 225. In this configuration, each of the buslines 224, 225 are sized to collect the current passing from each of their connected interdigitated fingers 229A and deliver the collected current to the driven external load “L” outside the formed solar cell 1300 during operation.

It is believed that by use of a compliant insulating material 1391 and/or a compliant conductive material 1392 the stress generated in the formed solar cell 1300 can be reduced versus conventional configurations by allowing the complaint insulating material 1391 and/or compliant conductive material 1392 to deform due to the stress generated during the solar cell 1300 formation process. The relaxed stress due to the deformation of the insulating material 1391 and/or conductive material 1392, will thus reduce the likelihood that the stress created during processing will affect the solar cell fabrication process device yield or the average solar cell lifetime. In one embodiment, it is desirable to size the cross-section of the compliant insulating material 1391 and/or compliant conductive material 1392 so that it will primarily bend or distort under the stress applied to it by the substrate 110 and/or the external interconnect structure 220. Therefore, it is generally desirable control the layer thickness and material properties of the insulating material 1391 and/or conductive material 1392, so that a desired amount of stress in the formed solar cell can be relaxed. In one embodiment, it is desirable to form the insulating material 1391 and conductive material 1392 from elastomeric materials due to their low modulus of elasticity and large elongation at failure.

While the foregoing is directed to embodiments of the present invention, other and further embodiments of the invention may be devised without departing from the basic scope thereof, and the scope thereof is determined by the claims that follow.

What is claimed is:

1. A flexible interconnect structure used to electrically connect portions of a first solar cell device to a second solar cell device, comprising:
a first conductive layer;
a second conductive layer; and
a dielectric material separating the first conductive layer from the second conductive layer, wherein the first conductive layer comprises one or more first interconnection regions that are configured to contact one or more first conductive features formed on a substrate surface of a solar cell substrate and the second conductive layer comprises one or more second interconnection regions that are configured to contact one or more second conductive features formed on the substrate surface, and
wherein the solar cell substrate has an n-type region that is in communication with the one or more first conductive features and a p-type region that is in communication with the one or more second conductive features.

2. The interconnect structure of claim 1, wherein the dielectric material is a material selected from a group consisting of polytetrafluoroethylene, polyethylene terephthalate, polyimide, nylon and polyvinyl chloride.

3. The interconnect structure of claim 1, wherein the thickness of the first conductive layer and the second conductive layer in the flexible interconnect structure is between about 20,000 Å and about 500,000 Å and the thickness of the one or more first conductive features and the one or more second conductive features are less than the thickness of the first conductive layer and the second conductive layer.

4. The interconnect structure of claim 1, wherein the solar cell substrate has a higher mechanical stiffness than the first flexible interconnect structure in a direction that is parallel to the substrate surface.

5. The interconnect structure of claim 1, wherein the first and second conductive layers in the flexible interconnect structure and the one or more first conductive features and the one or more second conductive features on the solar cell substrates are adapted to form part of an electrical circuit through which the current generated in the first solar cell device is configured to flow, and the electrical resistance of the electrical circuit formed through the first conductive layer or the second conductive layer is less than the electrical resistance through the one or more first conductive features or the one or more second conductive features.

6. A method of forming a solar cell device, comprising:
positioning a flexible interconnect structure over a solar cell substrate so that a portion of a first conductive layer of the flexible interconnect structure is in electrical communication with an n-type region disposed on a solar cell substrate and a portion of a second conductive layer is in electrical communication with a p-type region disposed on the solar cell substrate,
wherein a dielectric material disposed in the flexible interconnect structure separates the first conductive layer from the second conductive layer, and wherein the portion of the first conductive layer and the portion of the second conductive layer are in contact with a first surface of the flexible interconnect structure.

7. The method of claim 6, wherein the solar cell substrate has a higher mechanical stiffness than the flexible interconnect structure in a direction that is parallel to a surface of the solar cell substrate on which the n-type region and the p-type region are disposed.

8. The method of claim 6, wherein the dielectric material is a material selected from a group consisting of polytetrafluoroethylene, polyethylene terephthalate, polyimide, nylon and polyvinyl chloride.

9. The method of claim 6, wherein the thickness of the first conductive layer and the second conductive layer in the flexible interconnect structure is between about 20,000 Å and about 500,000 Å and the thickness of the first conductive feature and the second conductive feature is less than the thickness of the first conductive layer and the second conductive layer.

10. The method of claim 6, wherein the n-type region is in electrical communication with a first conductive feature disposed on a surface of the solar cell substrate and the p-type region is in electrical communication with a second conductive feature disposed on the surface, and the method further comprises:
disposing a conductive material on a region of the first conductive feature and on two or more regions of the second conductive feature, wherein at least a portion of the conductive material is disposed between the flexible interconnect structure and the surface of the substrate, and the region of conductive material disposed on the first conductive feature is at least a first distance from the two or more regions of conductive material deposited on the second conductive feature.

11. The method of claim 10, wherein the first distance is greater than about 0.1 mm.

12. A method of forming a solar cell device, comprising:
receiving a solar cell substrate having an n-type region and a p-type region that form part of a junction that is adapted to convert light into electrical energy, wherein the n-type region is in electrical communication with a first conductive feature disposed on a surface of the solar cell substrate and the p-type region is in electrical communication with a second conductive feature disposed on the surface;
positioning an interconnect structure having a first layer, a first hole formed through the first layer, a second layer, a second hole formed through the second layer and a dielectric material separating the first layer from the second layer against the surface of the solar cell substrate so that the first layer is in electrical communication with the first conductive feature and the second layer is in electrical communication with the second conductive feature; and
depositing a conductive material in the first hole and the second hole so that the conductive material creates a first conductive path between the first layer and the first conductive feature, and a second conductive path between the second layer and the second conductive feature.

13. The method of claim 12, wherein the conductive material is selected from a group consisting of tin (Sn), silver (Ag), lead (Pb) and a conductive polymer.

14. The method of claim 12, wherein the interconnect structure is disposed over the surface of the substrate and a region of the interconnect structure disposed between the first conductive feature and the second conductive features is not substantially coupled to the surface of the substrate.

15. A method of forming a solar cell device, comprising:
forming an enclosed region between one or more walls of an enclosure and an interconnect structure, where in the interconnect structure comprises:
a first layer;
a second layer;
a dielectric material disposed between the first layer and the second layer; and
a first hole and a second hole that are each in communication with the enclosed region and are formed through a portion of the interconnect structure;
positioning a first conductive feature formed on a solar cell substrate adjacent to the first layer, and a second conductive feature formed on the solar cell substrate adjacent to the second layer, wherein the first conductive feature is in electrical communication with an n-type region formed on the solar cell substrate and the second conductive feature is in electrical communication with a p-type region formed on the solar cell substrate;
heating the first conductive feature, the first layer, the second conductive feature and the second layer so that a bond is formed between the first conductive feature and the first layer and the second conductive feature and the second layer; and
urging the first conductive feature against the first layer and the second conductive feature against the second layer during the heating process.

16. The method of claim 15, wherein urging the first conductive feature against the first layer and the second conductive feature against the second layer during the heating process, comprises evacuating the enclosed region to form a sub-atmospheric pressure within the enclosed region and in the first and second holes to cause atmospheric pressure to urge the first conductive feature against the first layer and the second conductive feature against the second layer during the heating process.

17. The method of claim 15, wherein the first hole is formed through a portion of the first layer and the second hole is formed through a portion of the second layer.

18. A method of forming a solar cell device, comprising:
forming a solar cell substrate having an n-type region and a p-type region that form part of a junction that is adapted to convert light into electrical energy, wherein the n-type region is in electrical communication with a first conductive feature disposed on a surface of the solar cell substrate and the p-type region is in electrical communication with a second conductive feature disposed on the surface;
depositing a first compliant layer over the first conductive feature and the second conductive feature, wherein the first complaint layer has a first hole and a second hole formed therein;
depositing a conductive material in the first hole and the second hole, wherein the conductive material disposed in the first hole is in electrical communication with the first conductive feature and the conductive material disposed in the second hole is in electrical communication with the second conductive feature; and
positioning an interconnect structure having a first layer, a second layer, and a dielectric material separating the first layer from the second layer over a surface of the first compliant layer so that the first layer is in electrical communication with the first conductive feature through the first conductive material disposed in the first hole, and the second layer is in electrical communication with the second conductive feature through the first conductive material disposed in the second hole.

19. The method of claim 18, wherein the first conductive material comprises a metal selected from a group consisting of tin (Sn), silver (Ag), lead (Pb) and a conductive polymer.

20. The method of claim 18, wherein the first compliant layer is selected from a group consisting of silicone and epoxy.

21. The method of claim 18, further comprising heating the interconnect structure to form a bond between the solar cell substrate, the first compliant layer and the interconnect structure.

22. A plurality of interconnected solar cells, comprising:
a first solar cell assembly comprising:
a first solar cell substrate having an n-type region and a p-type region that are part of a junction that is adapted to convert light into electrical energy, wherein the n-type region is in electrical communication with a first conductive feature disposed on a surface of the first solar cell substrate and the p-type region is in electrical communication with a second conductive feature disposed on the surface; and
a first flexible interconnect structure having a first layer, a second layer and a dielectric material separating the first layer from the second layer, wherein the first layer is in electrical communication with the first conductive feature formed on the first solar cell substrate and the second layer is in electrical communication with a second conductive feature formed on the first solar cell substrate; and
a second solar cell assembly comprising:
a second solar cell substrate having an n-type region and a p-type region that are part of a junction that is adapted to convert light into electrical energy, wherein the n-type region is in electrical communication with a first conductive feature disposed on a surface of the second solar cell substrate and the p-type region is in electrical communication with a second conductive feature disposed on the surface; and
a second flexible interconnect structure having a first layer, a second layer and a dielectric material separating the first layer from the second layer, wherein the first layer is in electrical communication with the first conductive feature formed on the second solar cell substrate and the second layer is in electrical communication with a second conductive feature formed on the second solar cell substrate,
wherein the first layer in the first flexible interconnect structure is electrically connected to the first layer or the second layer of the second flexible interconnect structure.

23. The plurality of interconnected solar cells of claim 22, wherein the dielectric material in the first and second flexible interconnect structures is a material selected from a group consisting of polytetrafluoroethylene, polyethylene terephthalate, polyimide, nylon and polyvinyl chloride.

24. The plurality of interconnected solar cells of claim 22, wherein the thickness of the first conductive features and the second conductive features disposed on the surface of the first solar cell substrate and second solar cell substrate is between about 20 Å and about 5000 Å, and the thickness of the first layer and the second layer in the second flexible interconnect structure and second flexible interconnect structure is between about 20,000 Å and about 500,000 Å.

25. The plurality of interconnected solar cells of claim 22, wherein the first and second layers in the first and second flexible interconnect structures and the first conductive feature and the second conductive feature on the first and second solar cell substrates form part of an electrical circuit through which the generated current from the plurality of interconnected solar cells is configured to flow, and the electrical resistance of the electrical circuit formed through the first layer or the second layer is less than the electrical resistance through the first conductive feature or the second conductive feature.

26. The plurality of interconnected solar cells of claim 22, wherein the first solar cell substrate has a higher mechanical stiffness than the first flexible interconnect structure in a direction that is parallel to the surface of the first solar cell substrate.
